(19) United States
(12) Patent Application Publication
(10) Pub. No.: US 2025/0221109 A1
(43) Pub. Date: Jul. 3, 2025

(54) DISPLAY DEVICE AND MANUFACTURING METHOD OF THE SAME

(71) Applicant: Samsung Display Co., LTD., Yongin-si (KR)

(72) Inventor: Chan Woo JOO, Yongin-si (KR)

(21) Appl. No.: 18/802,965

(22) Filed: Aug. 13, 2024

(30) Foreign Application Priority Data
Dec. 29, 2023 (KR) 10-2023-0197248

(51) Int. Cl. H01L 33/46; H01L 25/16; H01L 33/38

(52) U.S. Cl. CPC H10H 20/841; H01L 25/167; H10H 20/8312; H10H 20/032; H10H 20/034

(57) ABSTRACT

The present disclosure may provide a display device and a method of manufacturing the same. A display device includes a substrate, a pixel electrode and a common electrode above the substrate and spaced apart from each other, and a light-emitting element including a first contact electrode above the pixel electrode, a second contact electrode above the common electrode, semiconductor layer stacks, a first protective layer surrounding the semiconductor layer stacks in plan view, a reflective layer on the first insulating layer, surrounding the semiconductor layer stacks in plan view, and not contacting the first contact electrode or the second contact electrode, and a second protective layer on the reflective layer and the first insulating layer, and surrounding the semiconductor layer stacks in plan view.

### CROSS-REFERENCE TO RELATED APPLICATION

The present application claims priority to, and the benefit of, Korean Patent Application No. 10-2023-0197248, filed on Dec. 29, 2023, in the Korean Intellectual Property Office, the entire disclosure of which is incorporated herein by reference.

### BACKGROUND

### 1. Field

The present disclosure relates to a display device, and a manufacturing method of the display device.

### 2. Description of the Related Art

The importance of display devices is increasing with the development of multimedia. In response to this, various types of display devices, such as organic light-emitting displays (OLED) and liquid crystal displays (LCD), are being used.

A display device that displays images includes a display panel, such as an organic light-emitting display panel or a liquid crystal display panel. Among them, the light-emitting display panel may include a light-emitting element, for example, a light-emitting diode (LED), an organic light-emitting diode (OLED) using an organic material as a light-emitting material, an inorganic light-emitting diode using an inorganic material as a light-emitting material, and the like.

### SUMMARY

Aspects of embodiments of the present disclosure provide a reflective layer on the side of the light-emitting element that may improve the light emission efficiency of the light-emitting element on the base substrate, and provide a method of 1 manufacturing a display device in which the base substrate and the light-emitting element may be easily separated, and a display device formed thereby.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes a substrate, a pixel electrode and a common electrode above the substrate and spaced apart from each other, and a light-emitting element including a first contact electrode above the pixel electrode, a second contact electrode above the common electrode, semiconductor layer stacks, a first protective layer surrounding the semiconductor layer stacks in plan view, a reflective layer on the first insulating layer, surrounding the semiconductor layer stacks in plan view, and not contacting the first contact electrode or the second contact electrode, and a second protective layer on the reflective layer and the first insulating layer, and surrounding the semiconductor layer stacks in plan view.

The reflective layer may define an opening overlapping the first contact electrode or the second contact electrode.

One end of the reflective layer may be adjacent a side surface of the semiconductor layer stacks, and may have a height that is lower than a height of the semiconductor layer stacks.

The semiconductor layer stacks may include an undoped semiconductor layer, a second semiconductor layer, an active layer, a first semiconductor layer, and a current-spreading layer.

The reflective layer may be adjacent side surfaces of the first semiconductor layer, the active layer, and the second semiconductor layer, and may be adjacent a portion of a side surface of the undoped semiconductor layer.

The second protective layer may cover one end of the reflective layer, and may directly contact the first protective layer.

The semiconductor layer stacks may define a downwardly convex groove penetrating the current-spreading layer, the first semiconductor layer, the active layer, and a portion of the second semiconductor layer, wherein the second contact electrode is in the groove, and is electrically connected to the second semiconductor layer.

The first protective layer may directly contact one surface of the semiconductor layer stacks, may define a first opening and a second opening adjacent another surface of the semiconductor layer stacks, and may be adjacent a side of the groove, wherein the second opening is adjacent a bottom surface of the groove.

The reflective layer might not overlap the first opening or the second opening, wherein the first contact electrode is electrically connected to the current-spreading layer through the first opening, and wherein the second contact electrode is electrically connected to the second semiconductor layer through the second opening.

The reflective layer may define an opening that overlaps the first opening or the second opening.

The reflective layer may be along a side of the groove.

According to one or more embodiments, a method of manufacturing display device includes forming semiconductor layer stacks by stacking semiconductor material layers on a base substrate and performing mesa patterning, forming a first insulating material layer above the base substrate to cover the semiconductor layer stacks, forming a photoresist above the base substrate, forming a reflective material layer covering the photoresist and the semiconductor layer stacks, removing the photoresist to form a reflective layer, forming a second insulating material layer covering the semiconductor layer stacks and the reflective layer above the base substrate, and forming a light-emitting element by forming a first contact electrode electrically connected to a first semiconductor layer of the semiconductor layer stacks, and a second contact electrode electrically connected to a second semiconductor layer of the semiconductor layer stacks, above a top surface of the semiconductor layer stacks.

The method may further include forming a first protective layer and forming a second protective layer surrounding the semiconductor layer stacks in plan view by etching portions of the first insulating material layer and the second insulating material layer extending from the semiconductor layer stacks to the base substrate.

The method may further include forming a downwardly convex groove in the semiconductor layer stacks through a partial etching process.

The semiconductor layer stacks may include an undoped semiconductor layer, the second semiconductor layer, an active layer, the first semiconductor layer, and a current-spreading layer, wherein the groove penetrates the current-spreading layer, the first semiconductor layer, the active layer, and a portion of the second semiconductor layer.

A height of the photoresist may be lower than a height of the undoped semiconductor layer.

The reflective layer might not contact the first contact electrode or the second contact electrode.

Forming the photoresist above the base substrate may include forming the photoresist at an area to overlap the first contact electrode or an area to overlap the second contact electrode on the top surface of the semiconductor layer stacks using a mask, wherein removing the photoresist includes forming an opening in the reflective layer.

The reflective material layer may be along an inside of the groove in the semiconductor layer stacks.

In forming the second insulating material layer, the second insulating material layer may cover one end of the reflective layer, and may directly contact the first insulating material layer.

According to one or more embodiments, a reflective layer formed on the side of the light-emitting element may improve the emission efficiency of the light-emitting element on the base substrate, and may facilitate the separation of the base substrate and the light-emitting element, thereby reducing or preventing the likelihood of non-separation or abnormal separation of the light-emitting element and the base substrate when the light-emitting element is transferred to the target substrate.

However, the aspects of the present disclosure are not limited to the aforementioned effects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments.

FIG. 2 is a plan view illustrating a display panel according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is an equivalent circuit diagram illustrating a sub-pixel according to one or more other embodiments.

FIG. 6 is a plan view illustrating sub-pixels according to one or more embodiments.

FIG. 7 is a cross-sectional view illustrating an example of a cross-section of a display panel taken along the line X1-X1′ in FIG. 6.

FIG. 8 is a cross-sectional view illustrating an example of area A of FIG. 7 in detail.

FIGS. 9 to 13 are cross-sectional views illustrating an example of area A of FIG. 7 in detail according to various embodiments.

FIG. 14 is a flowchart illustrating a method of manufacturing a display device according to one or more embodiments.

FIGS. 15 to 29 are diagrams to illustrate a method of manufacturing a display device according to one or more embodiments.

FIG. 30 is a diagram to illustrate a method for separating a light-emitting element from a base substrate according to one or more embodiments.

FIGS. 31 to 34 are drawings for forming a first reflective layer according to one or more other embodiments.

FIGS. 35 to 38 are diagrams for forming a first reflective layer according to one or more other embodiments.

FIGS. 39 to 42 are diagrams for forming a first reflective layer according to one or more other embodiments.

FIGS. 43 to 46 are diagrams for forming a first reflective layer according to one or more other embodiments.

FIG. 47 is a diagram schematically showing a virtual reality device including a display device according to one or more embodiments.

FIG. 48 is a diagram schematically showing a smart device including a display device according to one or more embodiments.

FIG. 49 is a diagram schematically showing a vehicle including a display device according to one or more embodiments.

FIG. 50 is a diagram schematically showing a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

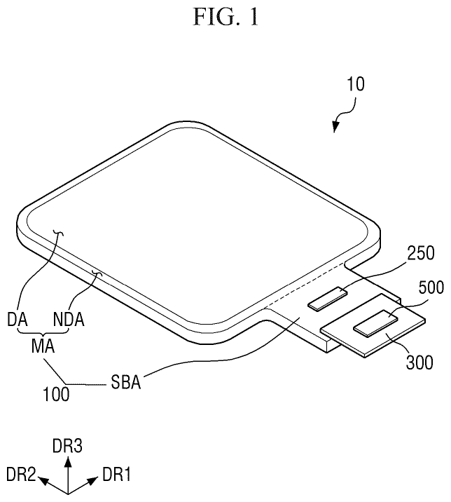

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IoT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light-emitting display device, but the embodiments are not limited thereto. Meanwhile, an ultra-small light-emitting diode is described hereinafter as a light-emitting element for ease of description. However, the type of light-emitting element that may be applied to the embodiments is not limited to ultra-small light-emitting diodes.

The display device 10 includes a display panel 100, a display driver 250, a circuit board 300, and a power supply circuit 500.

The display panel 100 may have a rectangular or square planar shape with sides extending in the first direction DR1 and sides extending in the second direction DR2 intersecting the first direction DR1. A corner where the sides in the first direction DR1 and the sides in the second direction DR2 meet may be rounded to have a curvature (e.g., predetermined curvature) or may be formed at a right angle. The planar shape of the display panel 100 is not limited to a square shape. For example, the display panel 100 may have another polygonal, circular, or elliptical planar shape. The display panel 100 may be formed flat but is not limited thereto. For example, the display panel 100 may be formed at the left and right ends and may include curved portions with a constant curvature or a varying curvature. In one or more embodiments, the display panel 100 may be flexibly formed to be able to be bent, curved, folded, or curled.

The substrate SUB of the display panel 100 may include a main area MA and a sub-area SBA.

The main area MA may include a display area DA that displays an image, and a non-display area NDA that is a peripheral area of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be located on, or below, the bottom surface of the display panel 100. When the sub-area SBA is bent, it may overlap the main area MA and the sub-area SBA in the third direction DR3, which is the thickness direction of the display panel 100. The display driver 250 may be located in the sub-area SBA.

The display driver 250 may generate signals and voltages for driving the display panel 100. The display driver 250 may be formed as an integrated circuit (IC) and attached to the display panel 100 using a chip-on-glass (COG) method, a chip-on-plastic (COP) method, or an ultrasonic bonding method, but is not limited thereto. In one or more embodiments, the display driver 250 may be attached to the circuit board 300 using a chip-on-film (COF) method.

The circuit board 300 may be attached to the sub-area SBA of the display panel 100. In one or more embodiments, the circuit board 300 may be attached to 1 pads of the display panel 100 located at one end of the sub-area SBA. Thereby, the circuit board 300 may be electrically connected to the display panel 100 and the display driver 250. The display panel 100 and the display driver 250 may receive digital video data, timing signals, and driving voltages through the circuit board 300. The circuit board 300 may be a flexible film, such as a flexible printed circuit board, a printed circuit board, or a chip on film.

The power supply circuit 500 may generate panel-driving voltages according to a power voltage supplied from the outside. The power supply circuit 500 may be formed as an integrated circuit (IC) and attached to the circuit board 300 using a COF method.

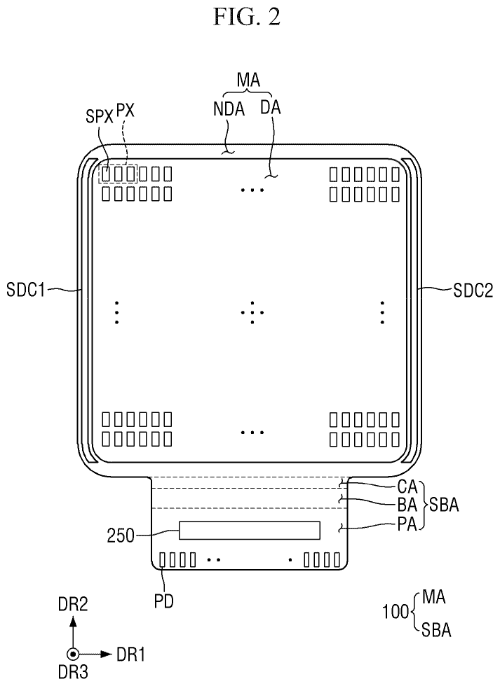

FIG. 2 is a plan view illustrating a display panel according to one or more embodiments. FIG. 2 illustrates that the sub-area SBA is unfolded without being bent.

Referring to FIGS. 1 and 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed in the center of the main area MA.

The display area DA may include unit pixels PX for displaying an image, and each unit pixel PX may include a plurality of sub-pixels SPX (or pixels). A unit pixel PX may be defined as a sub-pixel group of the smallest sub-pixel group capable of expressing a white grayscale.

The non-display area NDA may be placed adjacent to the display area DA. The non-display area NDA may be an area outside the display area DA. The non-display area NDA may be arranged to surround the display area DA (e.g., in plan view). The non-display area NDA may be an edge area of the display panel 100.

A first scan driver SDC1 and a second scan driver SDC2 may be located in the non-display area NDA. The first scan driver SDC1 is located at one side (for example, the left side) of the display panel 100, and the second scan driver SDC2 is located at the other side (for example, the right side) of the display panel 100. However, it is not limited to. Each of the first scan driver SDC1 and the second scan driver SDC2 may be electrically connected to the display driver 250 through scan fan-out lines. Each of the first scan driver SDC1 and the second scan driver SDC2 may receive a scan control signal from the display driver 250, may generate scan signals according to the scan control signal, and may output them to the scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub-area SBA is less than or substantially equal to the length of the first direction DR1 of the main area MA. The sub-area SBA may be curved, and thus a portion of the sub-area SBA may be located below the main area MA. For example, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may contact the non-display area NDA of the main area MA, and the other side of the connection area CA may contact the bending area BA.

The pad area PA is an area where the pads PD and the display driver 250 are located. The display driver 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may contact the bending area BA.

The bending area BA is a bent area. When the bending area BA is bent, the pad area PA may be located below the connection area CA and the main area MA. The bending area BA may be located between the connection area CA and the pad area PA. One side of the bending area BA may contact the connection area CA, and the other side of the bending area BA may contact the pad area PA.

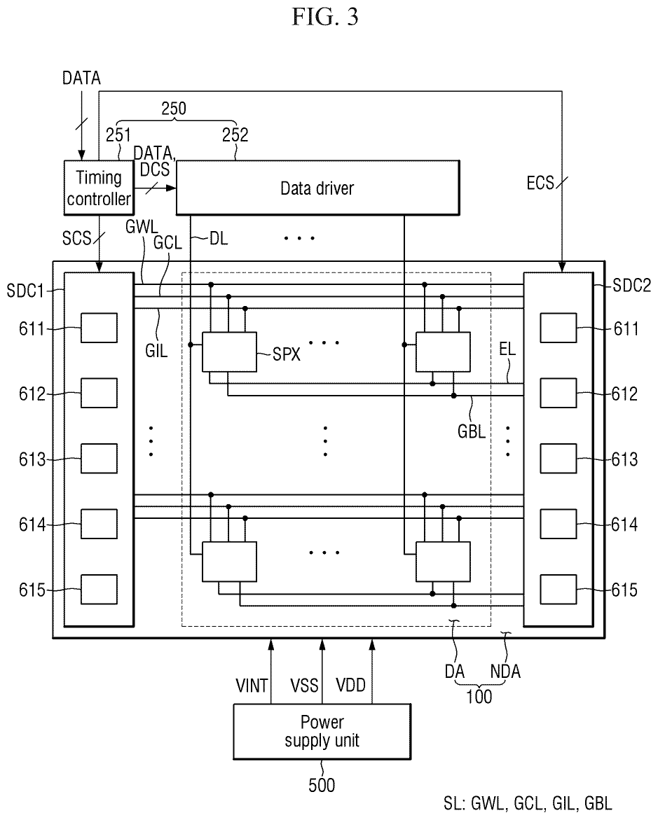

FIG. 3 is a block diagram illustrating a display device according to one or more embodiments.

Referring to FIGS. 1 to 3, the display area DA may be located unit pixels PX including each sub-pixel SPX, scan lines SL, light emission control lines EL, and data lines DL connected to the sub-pixels SPX.

The sub-pixels SPX may be arranged in a matrix form in the first direction DR1 and in the second direction DR2. The scan lines SL and the emission control lines EL may extend in the first direction DR1, and may be arranged in the second direction DR2. The data lines DL may extend in the second direction DR2, and may be arranged in the first direction DR1. The scan lines SL may include write scan lines GWL, control scan lines GCL, initialization scan lines GIL, and bias scan lines GBL located in each pixel row.

Each of the sub-pixels SPX may be connected to one or more of the write scan line GWL, one or more of control scan line GCL, one or more of initialization scan line GIL, one or more of bias scan line GBL, one or more of the emission control lines EL, and one or more of the data lines DL. For example, each sub-pixel SPX may be respectively connected to the write scan line GWL, the control scan line GCL, the initialization scan line GIL, the bias scan line GBL, and the light emission control line EL located in each pixel row, and the data line DL located in each pixel column.

Each of the sub-pixels SPX may be supplied with a data signal (e.g., a data voltage) of the data line DL according to the write scan signal supplied through the write scan line GWL, and may operate the light-emitting element according to the data signal.

The non-display area NDA includes a first scan driver SDC1, a second scan driver SDC2, and a display driver 250.

Each of the first scan driver SDC1 and the second scan driver SDC2 may include a write scan signal output unit 611, a control scan signal output unit 612, an initialization scan signal output unit 613, a bias scan signal output unit 614, and a light-emitting signal output unit 615. Each of the write scan signal output unit 611, the control scan signal output unit 612, the initialization scan signal output unit 613, the bias scan signal output unit 614, and the light-emitting signal output unit 615 may receive a scan-timing control signal SCS from the timing controller 251. The write scan signal output unit 611 may generate write scan signals according to the scan-timing control signal SCS of the timing controller 251, and may sequentially output them to the write scan lines GWL. The control scan signal output unit 612 may generate control scan signals according to the scan-timing control signal SCS, and may sequentially output them to the control scan lines GCL. The initialization scan signal output unit 613 may generate initialization scan signals according to the scan-timing control signal SCS, and may sequentially output them to the initialization scan lines GIL. The bias scan signal output unit 614 may generate bias scan signals according to the scan-timing control signal SCS, and may sequentially output them to the bias scan lines GBL. The light-emitting signal output unit 615 may generate light-emitting control signals according to the scan-timing control signal SCS, and may sequentially output them to the emission control lines EL.

The display driver 250 may include a timing controller 251 and a data driver 252.

The timing controller 251 may receive video data (DATA) (e.g., digital video data) and timing signals from an external source. The timing controller 251 may generate the scan-timing control signal SCS and the data-timing control signal DCS for controlling the display panel 100 according to timing signals. The timing controller 251 may output the scan-timing control signal SCS to the first scan driving portion SDC1 1 and the second scan driving portion SDC2. The timing controller 251 may output video data DATA and the data-timing control signal DCS to the data driver 252.

The data driver 252 may receive video data DATA and the data-timing control signal DCS from the timing controller 251. The data driver 252 may supply respective data signals (e.g., analog data voltages) to the sub-pixels SPX. For example, the data driver 252 may convert video data DATA into analog data voltages according to the data-timing control signal DCS, and may output them to the data lines DL. The sub-pixels SPX may be selected by the write scan signals of the first scan driving portion SDC1 and the second scan driving portion SDC2, and data signals may be supplied to the selected sub-pixels SPX.

The power supply circuit 500 may generate a plurality of panel-driving voltages according to an external power supply voltage. For example, the power supply circuit 500 may generate a first driving voltage VDD, a second driving voltage VSS, and a third driving voltage VINT, and may supply them to the display panel 100.

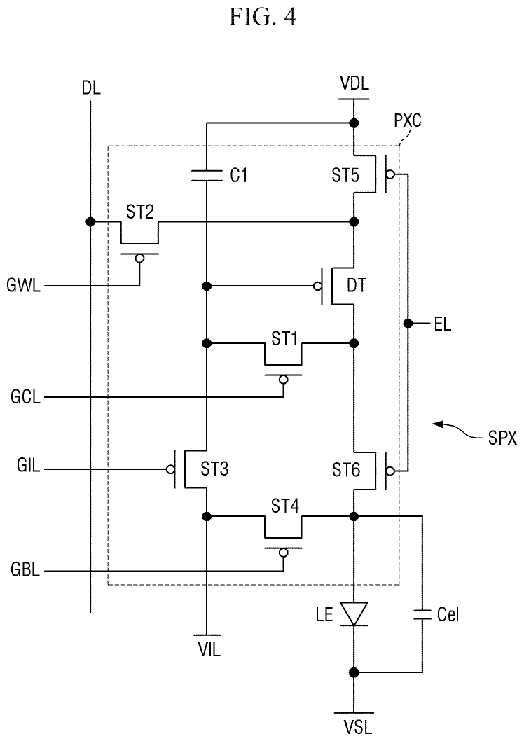

FIG. 4 is an equivalent circuit diagram illustrating a sub-pixel according to one or more embodiments.

Referring to FIG. 4, the sub-pixel SPX according to one or more embodiments may be connected to scan lines GWL, GIL, GCL, and GBL, an emission line EL, and a data line DL. For example, the sub-pixel SPX1 may be connected to the write scan line GWL, the initialization scan line GIL, the control scan line GCL, the bias scan line GBL, the emission line EL, and the data line DL.

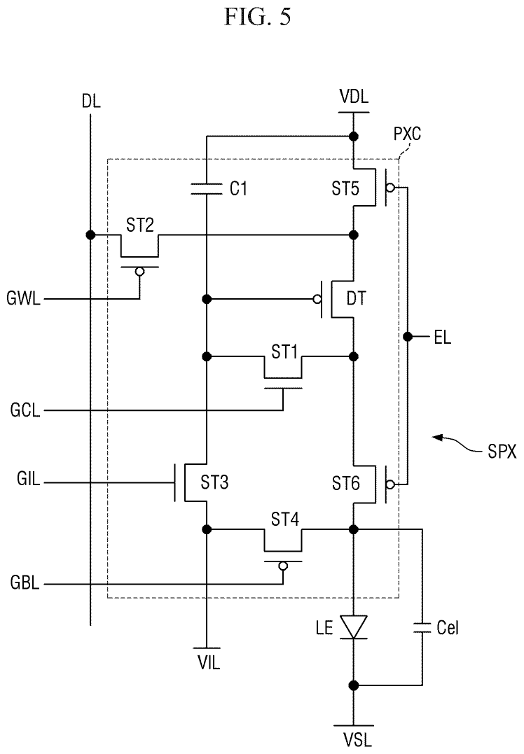

The sub-pixel SPX1 according to one or more embodiments includes a driving transistor DT, switch elements, a capacitor C1, and a light-emitting element LE1. The switch elements include first to sixth transistors ST1, ST2, ST3, ST4, ST5, and ST6. The driving transistor DT, the switch elements, and the capacitor C1 may be referred to as a pixel circuit PXC. The pixel circuit PXC may include the driving transistor DT, at least one switching transistor ST, and the capacitor C1. In one or more embodiments, the pixel circuit PXC may include first to sixth transistors ST1, ST2, ST3, ST4, ST5, and ST6 as the switching transistor ST. The configuration of the pixel circuit PXC is not limited to the embodiments of FIGS. 4 and 5, but may be varied.

The driving transistor DT includes a gate electrode, a first electrode, and a second electrode. The driving transistor DT controls the drain-source current (hereinafter referred to as “driving current”) flowing between the first electrode and the second electrode according to the data voltage applied to the gate electrode.

The light-emitting element LE1 may be a micro light-emitting diode. The light-emitting element LE emits light according to the driving current. The amount of light emitted from the light-emitting element LE may be proportional to the driving current. The anode electrode of the light-emitting element LE is connected to the first electrode of the fourth transistor ST4 and the second electrode of the sixth transistor ST6, and the cathode electrode may be connected to a second power supply line VSL to which a second power supply voltage is applied.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to 1 sixth transistors ST1, ST2, ST3, ST4, ST5, and ST6 are formed as p-type MOSFET, they may be turned on when a scan signal of the gate low voltage and an emission signal are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to an initialization voltage line VIL.

FIG. 5 is an equivalent circuit diagram illustrating a sub-pixel according to one or more other embodiments.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the emission line EL, respectively.

Alternatively, the fourth transistor ST4 in FIG. 4 may be formed of the n-type MOSFET. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

Alternatively, in one or more embodiments, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT may be formed of an oxide semiconductor.

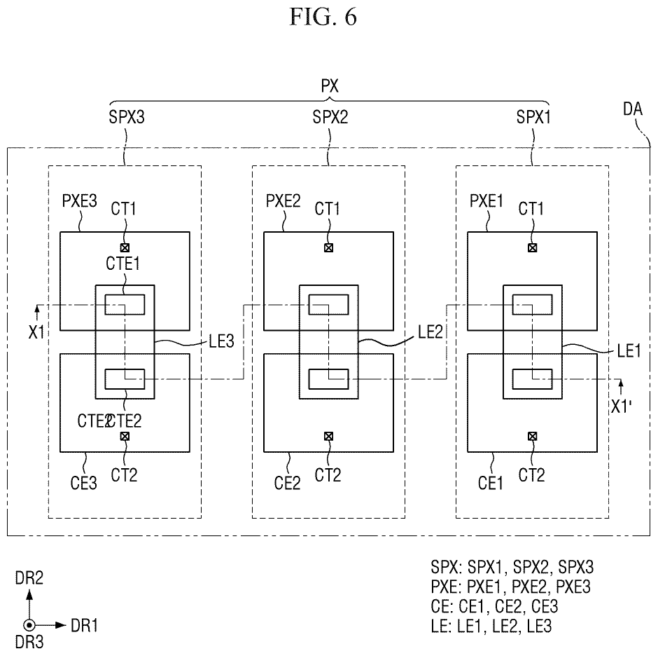

FIG. 6 is a plan view illustrating sub-pixels according to one or more embodiments. For example, FIG. 6 schematically illustrates a first sub-pixel SPX1, a second sub-pixel SPX2, and a third sub-pixel SPX3 located in the display area DA.

Referring to FIGS. 1 to 6, each of the unit pixels PX located in the display area DA includes the first sub-pixel SPX1, the second sub-pixel SPX2, and the third sub-pixel SPX3. In one or more embodiments, the first sub-pixel SPX1, the second sub-pixel SPX2, and the third sub-pixel SPX3 constituting one unit pixel PX may be arranged in the first direction DR1, but is not limited to this. For example, the arrangement of the sub-pixels SPX may vary depending on the embodiments.

FIG. 6 illustrates one or more embodiments in which a first sub-pixel SPX1, a second sub-pixel SPX2, and a third sub-pixel SPX3 constitute one unit pixel PX is disclosed, but the embodiments are not limited thereto. For example, the type, number, or ratio of sub-pixels SPX constituting each unit pixel PX may vary depending on embodiments.

In addition, in FIG. 6, the first sub-pixel SPX1, the second sub-pixel SPX2, and the third sub-pixel SPX3 (or the light-emitting areas of the first sub-pixel SPX1, the second sub-pixel SPX2, and the third sub-pixel SPX3) are substantially the same size and shape, the embodiments are not limited thereto. For example, the size or shape of the sub-pixels SPX may vary depending on embodiments. For example, the size of the sub-pixels SPX may be appropriately adjusted depending on the light efficiency of the sub-pixels SPX.

The first sub-pixel SPX1 may emit a first light, the second sub-pixel SPX2 may emit a second light, and the third sub-pixel SPX3 may emit a third light. In one or more embodiments, the first light may be light in a blue wavelength band, the second light may be light in a green wavelength band, and the third light may be light in a red wavelength band. In one example, the first light, the second light, and the third light may each be a blue light having a peak wavelength in the range of approximately 440 nm to approximately 480 nm, a green light having a peak wavelength in the range of approximately 510 nm to approximately 550 nm, and a red light having a peak wavelength in the range of approximately 610 nm to approximately 650 nm. The color or wavelength band of light emitted from each sub-pixel SPX may vary depending on embodiments.

The sub-pixels SPX may include each pixel electrode PXE, a common electrode CE, and a light-emitting element LE. For example, the first sub-pixel SPX1 may include a first pixel electrode PXE1, a first common electrode CE1, and a first light-emitting element LE1. The second sub-pixel SPX2 may include a second pixel electrode PXE2, a second common electrode CE2, and a second light-emitting element LE2. The third sub-pixel SPX3 may include a third pixel electrode PXE3, a third common electrode CE3, and a third light-emitting element LE3.

The pixel electrode PXE and the common electrode CE of each sub-pixel SPX may be spaced apart from each other in each sub-pixel area. For example, the first pixel electrode PXE1 and the first common electrode CE1 may be spaced apart from each other in the light-emitting area of the first sub-pixel SPX1. The second pixel electrode PXE2 and the second common electrode CE2 may be spaced apart from each other in the light-emitting area of the second sub-pixel SPX2. The third pixel 1 electrode PXE3 and the third common electrode CE3 may be spaced apart from each other in light-emitting area of the third sub-pixel SPX3.

Each light-emitting element LE may be located or bonded on the pixel electrodes PXE and the common electrodes CE. For example, the pixel electrodes PXE and the common electrodes CE may be bonding pads that are bonded to the respective light-emitting elements LE. In one or more embodiments, the pixel electrodes PXE and the common electrodes CE may be metal electrodes including a metal suitable for bonding but are not limited thereto.

FIG. 6 illustrates one or more embodiments in which each pixel electrode PXE and the common electrode CE have a rectangular planar shape, but the embodiments are not limited thereto. Also, although FIG. 6 illustrates one or more embodiments in which each pixel electrode PXE, light-emitting element LE, and common electrode CE are formed to have substantially the same size, the embodiments are not limited thereto. For example, the shape and size of the pixel electrode PXE, light-emitting element LE, and common electrode CE located in each sub-pixel SPX may be varied in different embodiments. The sub-pixels SPX may have substantially the same size pixel electrodes PXE and/or common electrodes CE, or the size of the pixel electrodes PXE and/or common electrodes CE may vary for each sub-pixel SPX.

Each pixel electrode PXE may be connected to the pixel circuit PXC of the corresponding sub-pixel SPX through a respective first connection hole CT1. For example, the first pixel electrode PXE1 may be connected to the pixel circuit PXC of the first sub-pixel SPX1, and the second pixel electrode PXE2 may be connected to the pixel circuit PXC of the second sub-pixel SPX2, and the third pixel electrode PXE3 may be connected to the pixel circuit PXC of the third sub-pixel SPX3.

Each common electrode CE may be connected to the second power supply line VSL to which the second driving voltage VSS is applied through a respective second connection hole CT2. For example, each of the first common electrode CE1, the second common electrode CE2, and the third common electrode CE3 may be connected to the second power supply line VSL through a respective second connection hole CT2. Accordingly, the second driving voltage VSS may be applied to the first common electrode CE1, the second common electrode CE2, and the third common electrode CE3.

FIG. 6 illustrates one or more embodiments in which the common electrodes CE of the sub-pixels SPX are individually separated, but the embodiments are not limited thereto. For example, the common electrodes CE located on a plurality of sub-pixels SPX located in the display area DA may be formed as a unit to form a single common electrode CE.

In one or more embodiments, each light-emitting element LE may include a first contact electrode CTE1 connected to each pixel electrode PXE. In one or more embodiments, each light-emitting element LE may further include a second contact electrode CTE2 connected to each common electrode CE.

In embodiments, the first light-emitting element LE1, the second light-emitting element LE2, and the third light-emitting element LE3 may emit different wavelengths of light. For example, the first light-emitting element LE1 may primarily emit first light, the second light-emitting element LE2 may primarily emit second light, and the third light-emitting element LE3 may primarily emit third light. In one or more embodiments, the first light may be light in a blue wavelength band, the second light may be light in a green wavelength band, and the third light may be light in a red wavelength band.

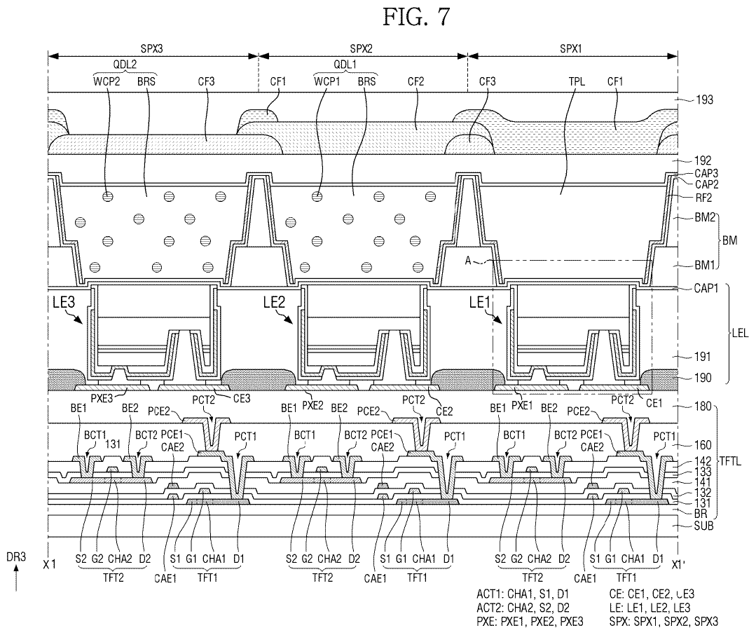

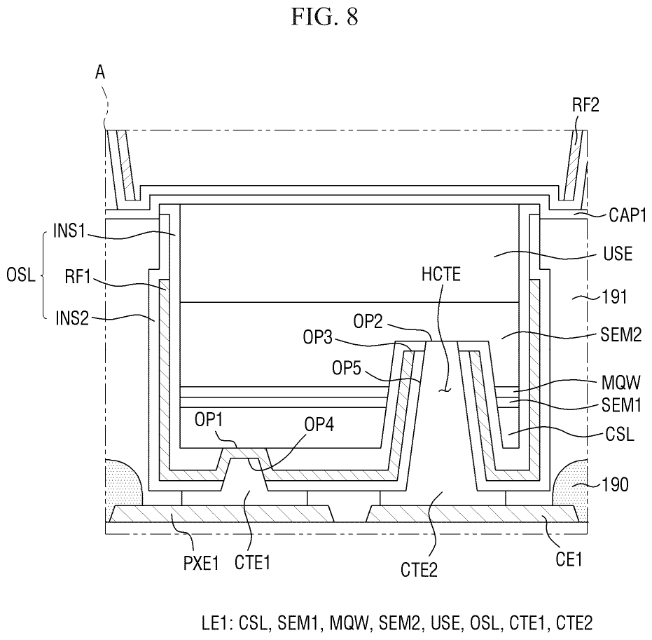

FIG. 7 is a cross-sectional view illustrating an example of a cross-section of a display panel taken along the line X1-X1′ in FIG. 6. FIG. 8 is a cross-sectional view illustrating an example of area A of FIG. 7 in detail.

Referring to FIGS. 7 and 8, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be located on the substrate SUB (as used herein, “located on” may mean “above”). The barrier film BR is a membrane for protecting the transistors of a thin film transistor layer TFTL from moisture penetrating through the substrate SUB, which may be vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and an aluminum oxide layer.

A first thin film transistor TFT1 may be located on the barrier film BR. The first thin film transistor TFT1 may be, for example, either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be located on the barrier film BR. The first active layer ACT1 of the first thin film transistor TFT1 may include polycrystalline silicon, single crystalline silicon, low-temperature polycrystalline silicon, or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be located on one side of the first channel area CHA1, and the first drain area D1 may be located on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate-insulating film 131 may be located on/above the first channel area CHA1, the first source area S1, and the first drain area D1 of the first thin film transistor TFT1. The first gate-insulating film 131 may be formed of an inorganic film, such as a silicon nitride layer, a silicon oxynitride layer, a silicon oxide layer, a titanium oxide layer, or an aluminum oxide layer.

A first gate metal layer may be located on the first gate-insulating film 131. The first gate metal layer may include the first gate electrode G1 and a first capacitor electrode CAE1 of the first thin film transistor TFT1. The first gate electrode G1 may overlap the first active layer ACT1 in the third direction DR3. In FIG. 7, the first gate electrode G1 and the first capacitor electrode CAE1 are shown to be located apart from each other, but the first gate electrode G1 and the first capacitor electrode CAE1 may be connected to each other. The first gate metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

A second gate-insulating film 132 may be located on the first gate electrode G1 and the first capacitor electrode CAE1 of the first thin film transistor TFT1. The second gate-insulating film 132 may be formed of an inorganic film, such as a silicon nitride layer, a silicon oxynitride layer, a silicon oxide layer, a titanium oxide layer, or an aluminum oxide layer.

A second gate metal layer may be located on the second gate-insulating film 132. The second gate metal layer may include a second capacitor electrode CAE2. The second capacitor electrode CAE2 may overlap the first capacitor electrode CAE1 of the first thin film transistor TFT1 in the third direction DR3. Because the second gate-insulating film 132 has a permittivity (e.g., predetermined permittivity), a capacitor (C1 in FIG. 5) may be formed by the first capacitor electrode CAE1, the second capacitor electrode CAE2, and the second gate-insulating film 132 located between them. The second gate metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

A first interlayer insulating film 141 may be located on the second capacitor electrode CAE2. The first interlayer insulating film 141 may be formed of an inorganic film, such as a silicon nitride layer, a silicon oxynitride layer, a silicon oxide layer, a titanium oxide layer, or an aluminum oxide layer.

A second thin film transistor TFT2 may be located on the first interlayer insulating film 141. The second thin film transistor TFT2 may be, for example, either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be located on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be located on one side of the second channel area CHA2, and the second drain area D2 may be located on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate-insulating film 133 may be located on the second active layer ACT2 of the second thin film transistor TFT2. The third gate-insulating film 133 may be formed of an inorganic film, such as a silicon nitride layer, a silicon oxynitride layer, a silicon oxide layer, a titanium oxide layer, or an aluminum oxide layer.

A third gate metal layer may be located on the third gate-insulating film 133. The third gate metal layer may include the second gate electrode G2 of the second thin film transistor TFT2. The second gate electrode G2 may overlap the second active layer ACT2 in the third direction DR3. The third gate metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

A second interlayer insulating film 142 may be located on the second gate electrode G2 of the second thin film transistor TFT2. The second interlayer insulating film 142 may be formed of an inorganic film, such as a silicon nitride layer, a silicon oxynitride layer, a silicon oxide layer, a titanium oxide layer, or an aluminum oxide layer.

A first data metal layer may be located on the second interlayer insulating film 142. The first data metal layer may include a first connection electrode PCE1, a second connection electrode BE1, and a third connection electrode BE2. The first connection electrode PCE1 may be connected to the first drain area D of the first active layer ACT1 through a first contact hole PCT1 that penetrates the first gate-insulating film 131, the second gate-insulating film 132, the first interlayer insulating film 141, the third gate-insulating film 133, and the second interlayer insulating film 142. The second connection electrode BE1 may be connected to the second source area S2 of the second active layer ACT2 through a second contact hole BCT1 penetrating the third gate-insulating film 133 and the second interlayer insulating film 142. The third connection electrode BE2 may be connected to the second drain area D2 of the second active layer ACT2 through a third contact hole BCT2 penetrating the third gate-insulating film 133 and the second interlayer insulating film 142. The first data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof. For example, the first data metal layer may include a first layer made of titanium (Ti), a second layer made of aluminum (Al), and a third layer made of titanium (Ti).

On the first connection electrode PCE1, on the second connection electrode BE1, and on the third connection electrode BE2, a first organic film 160 may be located for flattening the step difference caused by the first thin-film transistor TFT1 and the second thin-film transistor TFT2. The first organic film 160 may be formed from an organic film, such as an acrylic resin, an epoxy resin, a phenolic resin, a polyamide resin, a polyimide resin, or the like.

A second data metal layer (also referred to as a “second source-drain conductive layer”) may be located on the first organic film 160. The second data metal layer may include a fourth connection electrode PCE2. The fourth connection electrode PCE2 may be connected to the first connection electrode PCE1 through a fourth contact hole PCT2 penetrating the first organic film 160. The second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof. For example, the second data metal layer may include a first layer of titanium (Ti), a second layer of aluminum (Al), and a third layer of titanium (Ti).

A second organic film 180 may be located on the fourth connection electrode PCE2. The second organic film 180 may be formed from an organic film, such as an acrylic resin, an epoxy resin, a phenolic resin, a polyamide resin, a polyimide resin, or the like.

A light-emitting element layer LEL may be located on the second organic film 180. The light-emitting element layer LEL may include pixel electrodes PXE, common electrodes CE, light-emitting elements LE, a bank 190, a third organic layer 191, and a first capping layer CAP1.

Pixel electrodes PXE and common electrodes CE may be located on the second organic film 180. The pixel electrode PXE of each sub-pixel SPX may be connected to the fourth connection electrode PCE2 of the corresponding sub-pixel SPX through a first connection hole (e.g., CT1 in FIG. 6) penetrating the second organic film 180. The common electrode CE of each sub-pixel SPX may be connected to a second power supply line (e.g., VSL in FIG. 5) through a second connection hole (e.g., CT2 in FIG. 6) penetrating the second organic film 180.

In one or more embodiments, the pixel electrode PXE and the common electrode CE of each sub-pixel SPX might not overlap each other in the thickness direction of the light-emitting elements LE (for example, the third direction DR3), and may overlap with different parts of the light-emitting elements LE. For example, the first pixel electrode PXE1 and the first common electrode CE1 might not overlap each other in the thickness direction of the first light-emitting element LE1 of the first sub-pixel SPX1. Further, a portion of the first light-emitting element LE1 may be located on the first pixel electrode PXE1, and another portion of the first light-emitting element LE1 may be located on the first common electrode CE1.

The pixel electrodes PXE and common electrodes CE may be formed as a single layer or multiple layers of any one of molybdenum (Mo), aluminum (Al), chromium (Cr), gold (Au), titanium (Ti), nickel (Ni), neodymium (Nd), or copper (Cu), or alloys thereof. For example, the pixel electrodes PXE and the common electrodes CE may be formed as a multilayer of copper (Cu) or an alloy of titanium (Ti) and copper (Cu), which has a low surface resistance to lower the resistance of each of the pixel electrodes PXE and the common electrodes CE.

The bank 190 may cover a portion of each of the pixel electrodes PXE and the common electrodes CE. For example, the bank 190 may cover at least one edge of the pixel electrodes PXE and the common electrodes CE. The bank 190 might not be located on the remaining portions of the pixel electrodes PXE and the common electrodes CE. For example, the bank 190 may not be located on the center portion of each of the pixel electrodes PXE and common electrodes CE, and on the edges of the pixel electrodes PXE and common electrodes CE where the pixel electrodes PXE and common electrodes CE face each other.

The bank 190 may be formed of an organic film, such as an acrylic resin, epoxy resin, phenolic resin, polyamide resin, polyimide resin, or the like. The bank 190 may include a light-blocking material to reduce or prevent light from the light-emitting element LE of one sub-pixel SPX proceeding to the neighboring sub-pixel SPX. For example, the bank 190 may include an inorganic black pigment, such as carbon black or an organic black pigment.

Each light-emitting element LE may be located on the pixel electrodes PXE and the common electrodes CE. For example, a portion of the light-emitting element LE provided in the corresponding sub-pixel SPX may be located on the pixel electrode PXE of each sub-pixel SPX, and a different portion of the light-emitting element LE provided in the corresponding sub-pixel SPX may be located on the common electrode CE of each sub-pixel SPX. In one example, a first contact electrode CTE1 of each light-emitting element LE provided in the sub-pixel SPX may be located on the pixel electrode PXE of each sub-pixel SPX, and a second contact electrode CTE2 of each of the light-emitting elements LE provided in the corresponding sub-pixel SPX may be located on the common electrode CE of each sub-pixel SPX.

In the embodiments of FIGS. 7 and 8, each light-emitting element LE may be a flip-type micro-LED. The flip-type micro-LED may refer to an LED in which a first contact electrode CTE1 and a second contact electrode CTE2 are formed on one surface (e.g., the bottom surface) of the light-emitting element LE.

In one or more embodiments, each of the light-emitting elements LE may be formed of gallium nitride (GaN) or another inorganic material. In one or more embodiments, each of the light-emitting elements LE may be a micro light-emitting diode having a length in the first direction DR1, a length in the second direction DR2, and a length in the third direction DR3 of several to hundreds of μm, respectively. For example, the length of each of the light-emitting elements LE in the first direction DR1, the length in the second direction DR2, and the length in the third direction DR3 may each be about 100 μm or less.

Each of the light-emitting elements LE may be formed by growing on a semiconductor substrate, such as a silicon substrate or sapphire substrate. The light-emitting elements LE may be transferred directly from the semiconductor substrate onto the pixel electrodes PXE and the common electrodes CE of the display panel 100. Alternatively, the light-emitting elements LE may be transferred to the pixel electrodes PXE and common electrodes CE of the display panel 100 by electrostatic method using an electrostatic head or by stamping method using an elastic polymeric material, such as PDMS or silicone as a transfer substrate.

Each of the light-emitting elements LE may include a current-spreading layer CSL, a first semiconductor layer SEM1, an active layer MQW, a second semiconductor layer SEM2, an undoped semiconductor layer USE, and an outer shell layer OSL. In one or more embodiments, the current-spreading layer CSL may be omitted. In one or more embodiments, each of the light-emitting elements LE may further include at least one contact electrode CTE1 and CTE2. For example, each of the light-emitting elements LE may further include a first contact electrode CTE1 in electrical connection with the current-spreading layer CSL, and a second contact electrode CTE2 contacting the second semiconductor layer SEM2. In one or more embodiments, when the current-spreading layer CSL is omitted, the first contact electrode CTE1 may be electrically connected to the first semiconductor layer SEM1.

The first contact electrode CTE1 may be located on the pixel electrode PXE of the sub-pixel SPX. For example, the first contact electrode CTE1 may be located between the pixel electrode PXE of the sub-pixel SPX and the first semiconductor layer SEM1 of the light-emitting element LE. The first contact electrode CTE1 may connect the first semiconductor layer SEM1 of the light-emitting element LE to the pixel electrode PXE of the sub-pixel SPX.

The second contact electrode CTE2 may be located on the common electrode CE of the sub-pixel SPX. For example, the second contact electrode CTE2 may be located between the common electrode CE of the sub-pixel SPX and the second semiconductor layer SEM2 of the light-emitting element LE. The second contact electrode CTE2 may connect the second semiconductor layer SEM2 of the light-emitting element LE to the common electrode CE of the sub-pixel SPX.

The first contact electrode CTE1 and the second contact electrode CTE2 may include a metal, a metal oxide, or other conductive material. In one example, the first contact electrode CTE1 and the second contact electrode CTE2 may include any one of molybdenum (Mo), aluminum (Al), chromium (Cr), gold (Au), titanium (Ti), nickel (Ni), neodymium (Nd), or copper (Cu).

The current-spreading layer CSL is a layer to increase light extraction efficiency, and may be formed of a transparent conductive oxide (TCO), such as indium tin oxide (ITO) or indium zinc oxide (IZO) to allow light to pass through.

The first semiconductor layer SEM1 may be located on the first contact electrode CTE1. In one or more embodiments, the first semiconductor layer SEM1 may be made of GaN doped with a first conductivity type dopant (e.g., p-type dopant), such as Mg, Zn, Ca, Se, Ba, or the like.

The first semiconductor layer SEM1 may be electrically connected to the pixel electrode PXE of each sub-pixel SPX. For example, the first semiconductor layer SEM1 may be electrically connected to the pixel electrode PXE of each sub-pixel SPX through the first contact electrode CTE1.

The active layer MQW may be located on the first semiconductor layer SEM1. For example, the active layer MQW may be located between the first semiconductor layer SEM1 and the second semiconductor layer SEM2. The active layer MQW may emit light by recombination of electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In one or more embodiments, the well layer may be formed of InGaN, and the barrier layer may be formed of GaN or AlGaN but is not limited thereto. Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer MQW may shift to the red wavelength band, and as the content of indium (In) decreases, the wavelength band of light emitted by the active layer MQW may shift to the blue wavelength band. For example, the content of indium (In) in the active layer MQW of the light-emitting element LE that emits the third light (light in the blue wavelength band) may be approximately 10 wt % to approximately 20 wt %.

The second semiconductor layer SEM2 may be located on the active layer MQW. In one or more embodiments, the second semiconductor layer SEM2 may be n-GaN doped with a second conductive dopant (e.g., an n-type dopant), such as Si, Ge, Sn, or the like.

The second semiconductor layer SEM2 may be electrically connected to the common electrode CE of each sub-pixel SPX. For example, the second semiconductor layer SEM2 may be electrically connected to the common electrode CE of each sub-pixel SPX through the second contact electrode CTE2.

The undoped semiconductor layer USE may be located on the second semiconductor layer SEM2. The undoped semiconductor layer USE may be formed as a semiconductor layer that is not doped with an n-type dopant or a p-type dopant (e.g., an undoped semiconductor layer). For example, the undoped semiconductor layer USE may be any one of InAlGaN, GaN, AlGaN, InGaN, AlN, or InN that is not doped with a dopant. For example, the undoped semiconductor layer USE may be GaN that is not doped with a dopant.

An electron-blocking layer may be located between the first semiconductor layer SEM1 and the active layer MQW. The electron-blocking layer may be a layer to suppress or prevent too many electrons from flowing into the active layer MQW. For example, the electron-blocking layer may be p-AlGaN doped with p-type Mg. The thickness of the electron-blocking layer may be approximately 10 nm to approximately 50 nm. The electron-blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The thickness of the superlattice layer may be approximately 50 nm to approximately 200 nm. The superlattice layer may be omitted.

The light-emitting element LE has a groove HCTE on one surface that penetrates the current-spreading layer CSL, the first semiconductor layer SEM1, and the active layer MQW, and exposes the second semiconductor layer SEM2. The width or diameter of the groove HCTE may gradually increase from the second semiconductor layer SEM2 toward the current-spreading layer CSL. The second contact electrode CTE may be electrically connected to the second semiconductor layer SEM2 through the groove HCTE located in the current-spreading layer CSL, the first semiconductor layer SEM1, the active layer MQW, and the second semiconductor layer SEM2.

The outer shell layer OSL may include a first protective layer INS1, a first reflective layer RF1, and a second protective layer INS2.

The first protective layer INS1 may cover the outer surface of the light-emitting element LE except for one surface (e.g., the top surface of the light-emitting element LE). For example, it may surround the sides of the current-spreading layer CSL and the plurality of semiconductor layers, and may be located on one side of the current-spreading layer CSL. In one or more embodiments, the first protective layer INS1 may be located on a side of the groove HCTE (e.g., on or adjacent inner sides of the semiconductor layers).

The first protective layer INS1 may have two openings OP1 and OP2. The two openings OP1 and OP2 may be spaced apart from each other. The second opening OP2 may be arranged to overlap the bottom of the groove HCTE. That is, the second semiconductor layer SEM2 may be exposed through the second opening OP2 and the groove HCTE of the first protective layer INS1.

The first protective layer INS1 may include materials with insulating properties, for example, inorganic insulating materials, such as silicon oxide (SiOx), silicon nitride (SiNx), silicon oxynitride (SiOxNy), aluminum oxide (AlxOy), aluminum nitride (AlN), and the like.

In one or more embodiments, the first protective layer INS1 may be made of a single layer or a multilayer of materials with insulating properties. The first protective layer INS1 may reduce or prevent the likelihood of an electrical short circuit that may occur when the active layer MQW directly contacts an electrode through which an electrical signal is transmitted to the light-emitting element LE. Furthermore, because the first protective layer INS1 includes the active layer MQW and protects the outer surface of the light-emitting element LE, it is possible to reduce or prevent a decrease in luminous efficiency.

The first reflective layer RF1 is located on the first protective layer INS1, surrounds a portion of the side surface of the current-spreading layer CSL and of the plurality of semiconductor layers, and may be located on one side of the current-spreading layer CSL. For example, the first reflective layer RF1 may be formed to surround the sides of the current-spreading layer CSL and the plurality of semiconductor layers along the first protective layer INS1, but the first protective layer INS1 at both ends of the longitudinal sides of the current-spreading layer CSL and the plurality of semiconductor layers may be formed such that at least a portion of the first protective layer INS1 is exposed.

The first reflective layer RF1 may be lower than the height of the first protective layer INS1. One end of the first reflective layer RF1 and one end of the first protective layer INS1 have a step difference. For example, the first reflective layer RF1 may not be located on, or may not extend to, at least a portion of the undoped semiconductor layer USE.

The first reflective layer RF1 may not be electrically connected to at least one of the first contact electrode CTE1 or the second contact electrode CTE2. In one or more embodiments, the first reflective layer RF1 may have a third opening OP3, may cover the first opening OP1 of the first protective layer INS1, may extend to the side of the groove HCTE, and may overlap the second opening OP2 of the first protective layer INS1. Referring to FIG. 8, the first reflective layer RF1 may be electrically connected to the first contact electrode CTE1, and may not be electrically connected to the second contact electrode CTE2.

In one or more embodiments, the first reflective layer RF1 may include a metal material that is conductive and has a high light reflectance. The first reflective layer RF1 may include, for example, aluminum (Al) or silver (Ag), and alloys thereof, and may comprise a single layer or multiple layers thereof. The multiple layers may be, for example, two layers of titanium/copper, two layers of titanium/aluminum, two layers of nickel/aluminum, two layers of a silver/aluminum-silicon alloy, or the like.

Alternatively, the first reflective layer RF1 may include M pairs of first and second layers having different refractive indices, where M is an integer that is greater than or equal to 2, to act as Distributed Bragg Reflectors (DBR). In this case, the M first layers and M second layers may be arranged alternately. The first layer and the second layer may be formed of an inorganic layer, for example, a silicon nitride layer, a silicon oxy nitride layer, a silicon oxide layer, a titanium oxide layer, or an aluminum oxide layer.

Meanwhile, an adhesive layer may be further located between the first reflective layer RF1 and the first protective layer INS1. The adhesive layer may be made of Cr, Ti, or the like.

The second protective layer INS2 may be located on the first reflective layer RF1, and may be located on one side of the current separation layer CSL and the plurality of semiconductor layers, surrounding a portion of the side of the current-spreading layer CSL. The second protective layer INS2 may directly contact the first protective layer INS1 on the first protective layer INS1 where the first reflective layer RF1 is not located. For example, the second protective layer INS2 may directly contact the first protective layer INS1 on the side of the undoped semiconductor layer USE. Accordingly, one end of the first reflective layer RF1 may be surrounded by the second protective layer INS2.

The second protective layer INS2 may include a fourth opening OP4 overlapping the first opening OP1 of the first protective layer INS1, and a fifth opening OP5 overlapping the second opening OP2 of the first protective layer INS1.

The second protective layer INS2 may be formed of an inorganic film, such as a silicon nitride layer, a silicon oxynitride layer, a silicon oxide layer, a titanium oxide layer, or an aluminum oxide layer.

The first contact electrode CTE1 and the second contact electrode CTE2 may contact the lower layer through respective ones of the openings OP1, OP2, OP3, OP4, and OP5 or grooves HCTE of the outer shell layer OSL. In one or more embodiments, the first contact electrode CTE1 contacts the first reflective layer RF1 through the fourth opening OP4 of the second insulating layer INS2, which will be described later, and the first reflective layer RF1 may contact the current-spreading layer CSL through the first opening OP1 of the first insulating layer INS1. The second 1 semiconductor layer SEM2 may be exposed through the fifth opening OP5 of the second insulating layer INS2, the third opening OP3 of the reflective layer RF1, and the second opening OP2 of the first insulating layer INS1. The second contact electrode CTE2 may be located on the opening exposing the second semiconductor layer SEM2 and may contact the second semiconductor layer SEM2.

The third organic layer 191 may cover a portion of the side surfaces of the bank 190 and the plurality of light-emitting elements LE. The third organic layer 191 is a layer for flattening the steps caused by the plurality of light-emitting elements LE. The third organic layer 191 may be formed of an organic film, such as an acrylic resin, an epoxy resin, a phenolic resin, a polyamide resin, a polyimide resin, or the like.

The first capping layer CAP1 may be located on the third organic layer 191 and the light-emitting element LE. The first capping layer CAP1 may be formed from an inorganic film, such as a silicon nitride layer, a silicon oxynitride layer, a silicon oxide layer, a titanium oxide layer, or an aluminum oxide layer.

As shown in FIG. 7, a light-blocking layer BM, a light transmission layer TPL, a first light conversion layer QDL1, and a second light conversion layer QDL2 may be located on the first capping layer CAP1. However, the embodiments are not limited to this, and a third light conversion layer may be located instead of the light transmission layer TPL. In this case, the third light conversion layer may include a material that is different from the first light conversion layer QDL1 and the second light conversion layer QDL2. For example, the first light conversion layer QDL1 may include a quantum dot that converts light in a blue wavelength band to light in a green wavelength band, the second light conversion layer QDL2 may include a quantum dot that converts light in a blue wavelength band to light in a red wavelength band, and the third light conversion layer, when included, may include a blue phosphor. In addition, each of the first light conversion layer QDL1, the second light conversion layer QDL2, and the third light conversion layer may include quantum dots and a light diffusion agent, such as titanium dioxide (TiO₂). In this case, the number of titanium dioxide (TiO₂) particles in 1 the third light conversion layer may be greater than the number of titanium dioxide (TiO₂) particles in the first light conversion layer QDL1 or the number of titanium dioxide (TiO₂) particles in the second light conversion layer QDL2.

The light transmission layer TPL, the first light conversion layer QDL1, and the second light conversion layer QDL2 may be formed in the respective light-emitting area compartmentalized by the light-blocking layer BM. For example, the light transmission layer TPL is located on the first capping layer CAP1 in the first sub-pixel SPX1, and the first light conversion layer TPL is located on the first capping layer CAP1 in the second sub-pixel SPX2, and the second light conversion layer QDL2 may be located on the first capping layer CAP1 in the third sub-pixel SPX3. The light-blocking layer BM may overlap the bank 190 in the third direction DR3, and may not overlap the light-emitting elements LE.

The light transmission layer TPL may include a light-transmitting organic material. For example, the light transmission layer TPL may include an epoxy-based resin, an acrylic-based resin, a cardo-based resin, or an imide-based resin.

The first light conversion layer QDL1 may convert a portion of the first light (light in the blue wavelength band) incident from the light-emitting element LE into second light (light in the green wavelength band). The first light conversion layer QDL1 may include a first base resin BRS1 and first wavelength conversion particles WCP1. The first base resin BRS1 may include a light-transmitting organic material. For example, the first base resin BRS1 may include an epoxy-based resin, an acrylic-based resin, a cardo-based resin, or an imide-based resin. The first wavelength conversion particle WCP1 may convert a portion of the first light (light in the blue wavelength band) incident from the light-emitting element LE into second light (light in the green wavelength band). The first wavelength conversion particle WCP1 may be a quantum dot (QD), a quantum rod, a fluorescent material, or a phosphorescent material. The first light conversion layer QDL1 may further include a light diffusion agent, such as titanium dioxide (TiO₂).

The second light conversion layer QDL2 may convert a portion of the first light (light in the blue wavelength band) incident from the light-emitting element LE into third light (light in the red wavelength band). The second light conversion layer QDL2 may include a second base resin BRS2 and second wavelength conversion particles WCP2. The second base resin BRS2 may include a light-transmitting organic material. For example, the second base resin BRS2 may include an epoxy-based resin, an acrylic-based resin, a cardo-based resin, or an imide-based resin. The second wavelength conversion particle WCP2 may convert a portion of the first light (light in the blue wavelength band) incident from the light-emitting element LE into third light (light in the red wavelength band). The second wavelength conversion particle WCP2 may be a quantum dot (QD), a quantum rod, a fluorescent material, or a phosphorescent material. The second light conversion layer QDL2 may further include a light diffusion agent, such as titanium dioxide (TiO₂).

The light-blocking layer BM may include a first light-blocking layer BM1 and a second light-blocking layer BM2 that are sequentially stacked. A length in the first direction DR1 or a length in the second direction DR2 of the first light-blocking layer BM1 may be greater than a length in the first direction DR1 or a length of the second direction DR2 of the second light-blocking layer BM. The length (or height) of the first light-blocking layer BM1 in the third direction DR3 may be greater than the length (or height) of the second light-blocking layer BM2 in the third direction DR3. The first light-blocking layer BM1 and the second light-blocking layer BM2 may include an organic film formed of an acrylic resin, an epoxy resin, a phenolic resin, a polyamide resin, a polyimide resin, or the like. For example, the first light-blocking layer BM1 and the second light-blocking layer BM2 may include an inorganic black pigment, such as carbon black or an organic black pigment.

The second capping layer CAP2 may be located on the first capping layer CAP1 and the light-blocking layer BM. The second capping layer CAP2 may be located on the side and top surfaces of the light-blocking layer BM. That is, the second 1 capping layer CAP2 may be located on the side of the first light-blocking layer BM1 and the side and top surfaces of the second light-blocking layer BM2. The second capping layer CAP2 protects the first wavelength conversion particles WCP1 of the first light conversion layer QDL1 and the second wavelength conversion particles WCP2 of the second light conversion layer QDL2 from moisture penetration, and thus may surround the top, bottom, and side(s) of the first light conversion layer QDL1 and the second light conversion layer QDL2.

The second reflective layer RF2 may be located between the light-blocking layer BM and the light transmission layer TPL, between the light-blocking layer BM and the first light conversion layer QDL1, and between the light-blocking layer BM and the second light conversion layer QDL2. The second reflective layer RF2 may be located on the second capping layer CAP2 located on the side of the first light-blocking layer BM1 and the side of the second light-blocking layer BM2. The second reflective layer RF2 serves to reflect light traveling in the lateral direction from the first light conversion layer QDL1, the second light conversion layer QDL2, and the light transmission layer TPL.

The second reflective layer RF2 may include a highly reflective metal material, such as aluminum (Al). The thickness of the second reflective layer RF2 may be approximately 0.1 μm.

Alternatively, the second reflective layer RF2 may include M pairs of first and second layers with different refractive indices, where M is an integer greater than or equal to 2, to act as Distributed Bragg Reflectors (DBR). In this case, M first layers and M second layers may be arranged alternately. The first layer and the second layer may be formed of an inorganic film, such as a silicon nitride layer, a silicon oxynitride layer, a silicon oxide layer, a titanium oxide layer, or an aluminum oxide layer.

The third capping layer CAP3 may be located on the second capping layer CAP2, the light transmission layer TPL, the first light conversion layer QDL1, and the second light conversion layer QDL2. The third capping layer CAP3 may be formed of 1 an inorganic film, such as a silicon nitride layer, a silicon oxynitride layer, a silicon oxide layer, a titanium oxide layer, or an aluminum oxide layer. The light transmission layer TPL, the first light conversion layer QDL1, and the second light conversion layer QDL2 may be encapsulated by a first capping layer CAP1, a second capping layer CAP2, and a third capping layer CAP3. The refractive index of the third capping layer CAP3 may be lower than the refractive index of the second capping layer CAP2. Further, the refractive index of the third capping layer CAP3 may be lower than the refractive index of the fourth organic layer 192.

A fourth organic layer 192 may be located on the second capping layer CAP2. The fourth organic layer 192 may be formed from an acrylic resin, an epoxy resin, a phenolic resin, a polyamide resin, a polyimide resin, or the like.

Color filters may be located on the fourth organic layer 192. The color filters may include first color filters CF1, second color filters CF2, and third color filters CF3. However, the embodiments are not limited thereto. For example, when the light-emitting elements LE of the first sub-pixel SPX1 emit light of a first color, the light-emitting elements LE of the second sub-pixel SPX2 emit light of a second color, and the light-emitting elements LE of the third sub-pixel SPX3 emit light of a third color, the light transmission layer TPL, the first light conversion layer QDL1, the second light conversion layer QDL2, and/or the blocking layer BM may be omitted. Further, in this case, the fourth organic layer 192 may be located on the first capping layer CAP1, and color filters may be located on the fourth organic layer 192, or the color filters may be omitted.

The first color filter CF1 may be located in the first sub-pixel SPX1. The first color filter CF1 may transmit first light (e.g., light in a blue wavelength band). For example, the first color filter CF1 may transmit the first light emitted from the light-emitting element LE and passing through the light transmission layer TPL. Accordingly, the first sub-pixel SPX1 may emit first light.

The second color filter CF2 may be located in the second sub-pixel SPX2. The second color filter CF2 may transmit second light (e.g., light in the green wavelength band), and may absorb or block the first light. For example, the second color filter CF2 may transmit the second light converted by the first light conversion layer QDL1 among the first light emitted from the light-emitting element LE, and may absorb or block the first light that has not been converted by the first light conversion layer QDL1.

The third color filter CF3 may be located in the third sub-pixel SPX3. The third color filter CF3 may transmit the third light (e.g., light in the red wavelength band), and may absorb or block the first light. For example, the third color filter CF3 may transmit the third light converted by the second light conversion layer QDL2 among the first light emitted from the light-emitting element LE, and may absorb or block the first light not converted by the first light conversion layer QDL1. Accordingly, the third sub-pixel SPX3 may emit third light.

Each of the first, second, and third color filters CF1, CF2, and CF3 may block external light incident from the outside. For example, the third color filter CF3 may increase the purity (color purity) of the O color corresponding to the third light in the red wavelength band by blocking the first light, which is light in the blue wavelength band, and the second light, which is light in the green wavelength band, incident from the outside.

The first color filter CF1, the second color filter CF2, and the third color filter CF3 may overlap the bank 190 and the light-blocking layer BM in the third direction DR3.

A fifth organic layer 193 for planarization may be located on the first, second, and third color filters CF1, CF2, and CF3. The fifth organic layer 193 may be formed from an acrylic resin, an epoxy resin, a phenolic resin, a polyamide resin, a polyimide resin, or the like.

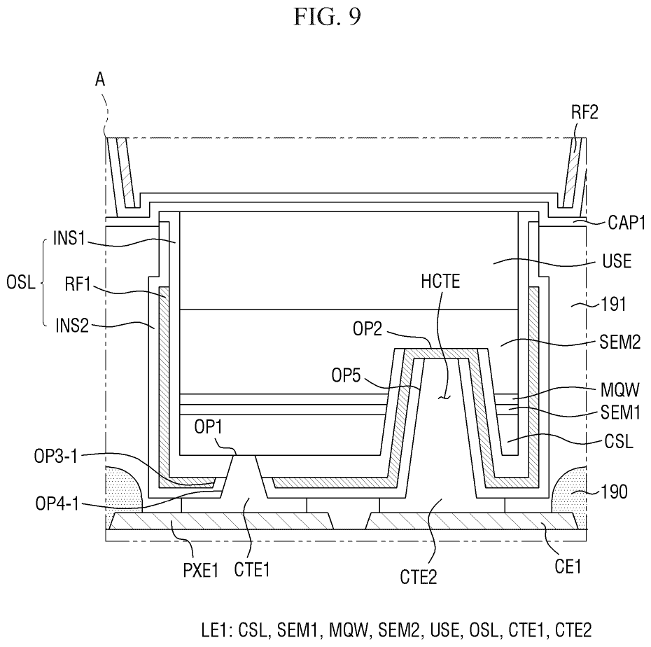

FIGS. 9 to 13 are cross-sectional views illustrating an example of area A of FIG. 7 in detail according to various embodiments.

In FIGS. 9 to 13, the first reflective layer RF1 arrangement, number, and location of the openings differ from the first reflective layer RF1 arrangement, number, and location of the openings of FIG. 8, and repeated descriptions that are redundant with the one or more embodiments corresponding to FIG. 8 are omitted.

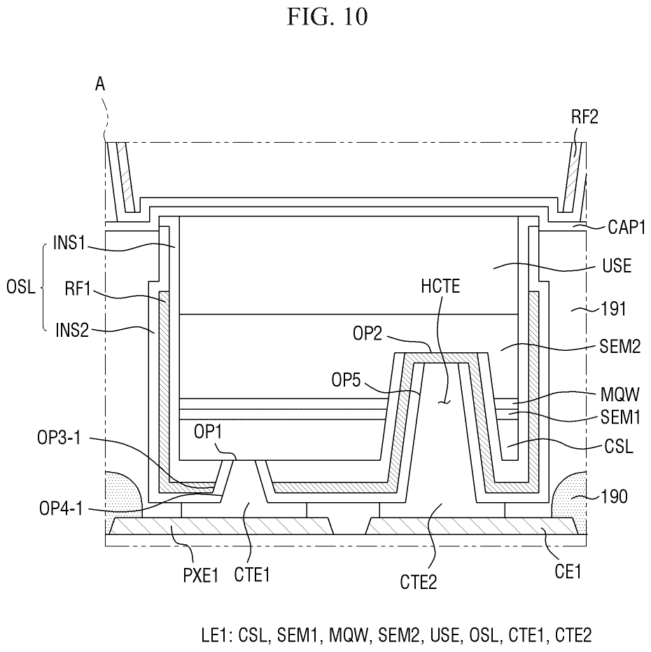

Referring to FIGS. 9 and 10, the first reflective layer RF1 may be located on top of the first insulating layer INS1 and may be located on one side of the current-spreading layer CSL, while surrounding the current-spreading layer CSL and a portion of the side of the plurality of semiconductor layers. The first reflective layer RF1 may be lower than the height of the first protective layer INS1. One end of the first reflective layer RF1 and one end of the first protective layer INS1 have a step difference. For example, the first reflective layer RF1 may not be located on at least a portion of the undoped semiconductor layer USE. A third opening OP3-1 of the first reflective layer RF1 may be located at a position overlapping the first opening OP1 of the first protective layer INS1. The diameter of the third opening OP3-1 of the first reflective layer RF1 may be located wider than the diameter of the first opening OP1 of the first protective layer INS1. The third opening OP3-1 of the first reflective layer RF1 may have a step difference from the first opening OP1 of the first protective layer INS1.

The second protective layer INS2 may have a fourth opening OP4-1 that overlaps the third opening OP3-1.

As shown in FIGS. 9 and 10, the first reflective layer RF1 may be surrounded by the first protective layer INS1 and the second protective layer INS2. Accordingly, the first contact electrode CTE1 may not be electrically connected to the first reflective layer RF1. As shown in FIG. 9, the second protective layer INS2 may be located along the third opening OP3-1 of the first reflective layer RF1. Alternatively, as shown in FIG. 10, the second protective layer INS2 may be located along the sides of the third opening OP3-1 of the first reflective layer RF1 and the sides of the first opening OP1 of 1 the first protective layer INS1, but not at the bottom of the first opening OP1 to expose the current-spreading layer CSL. Therefore, the first contact electrode CTE1 may be electrically connected to the first semiconductor layer SEM1 by directly contacting the current-spreading layer CSL through the first opening OP1, the third opening OP3-1, and the fourth opening OP4-1.

Additionally, the first reflective layer RF1 may extend along the side of the groove HCTE, and may cover the second opening OP2 of the first protective layer INS1. Accordingly, the first reflective layer RF1 may directly contact the exposed second semiconductor layer SEM2 through the second opening OP2. The first reflective layer RF1 may be electrically connected to the second contact electrode CTE2 at a position overlapping the second opening OP2 of the first protective layer INS1.

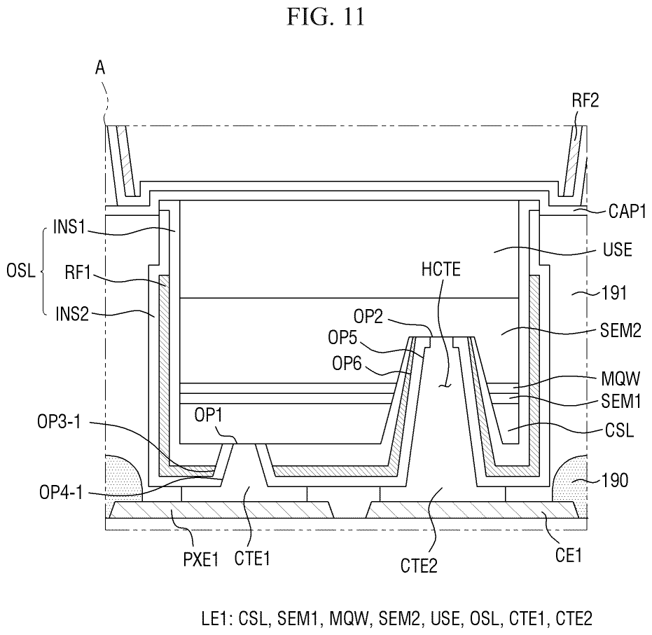

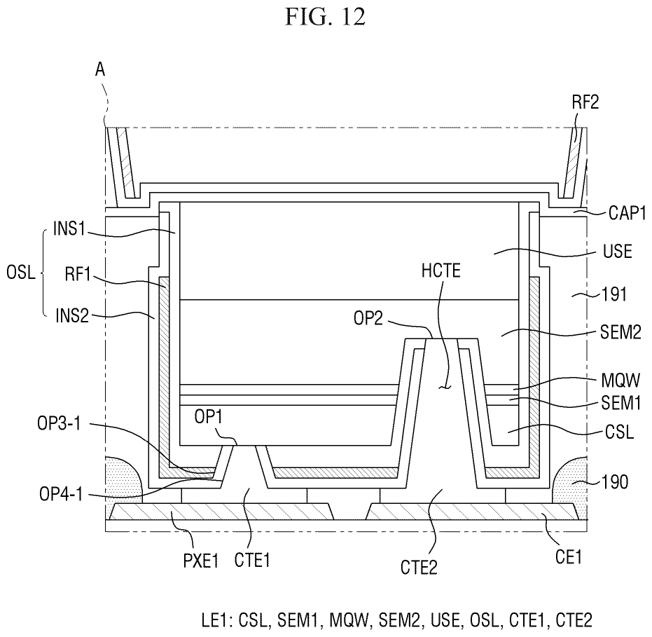

As shown in FIGS. 11 and 12, the first reflective layer RF1 may have two openings overlapping the first opening OP1 and the second opening OP2 of the first protective layer INS1, respectively. Further, the first reflective layer RF1 may be completely surrounded by the first protective layer INS1 and the second protective layer INS2.

As shown in FIG. 11, the first reflective layer RF1 may define a third opening OP3-1 and a sixth opening OP6.

The sixth opening OP6 of the first reflective layer RF1 may overlap the second opening OP2 of the first reflective layer RF1.

The second protective layer INS2 is located along the sides of the third opening OP3-1 of the first reflective layer RF1 and the side of the first opening OP1 of the first protective layer INS1, but is not located at the bottom of the first opening OP1 (e.g., the bottom of the current-spreading layer CSL) to expose the current-spreading layer CSL. Therefore, the first contact electrode CTE1 may be electrically connected to the first semiconductor layer SEM1 in direct contact with the current-spreading layer CSL through the first opening OP1, the third opening OP3-1, and the fourth opening OP4-1.

The second protective layer INS2 is located along the side of the sixth opening OP6 of the first reflective layer RF1, but is not located at the bottom of the sixth opening OP6 to expose the second semiconductor layer SEM2. Accordingly, the second contact electrode CTE2 may be electrically connected to the second semiconductor layer SEM2 through the second opening OP2, the sixth opening OP6, and the fifth opening OP5.

Referring to FIG. 12, the first reflective layer RF1 may differ from FIG. 11 in that it is not located on the side of the groove HCTE. Accordingly, the sides of the groove HCTE may directly contact the first protective layer INS1 and the second protective layer INS2.

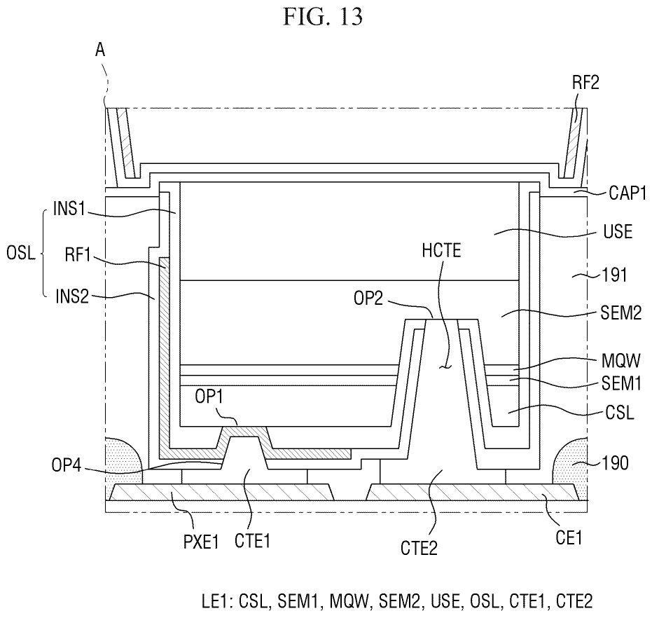

Referring to FIG. 13, the first reflective layer RF1 may differ from FIG. 8 in that it does not overlap the second contact electrode CTE2. Accordingly, the sides of the groove HCTE may directly contact the first protective layer INS1 and the second protective layer INS2.

Referring to FIGS. 7 to 13, the first reflective layer RF1 has a step in the longitudinal direction of the first protective layer INS1, the second protective layer INS2, and the light-emitting element LE. The first reflective layer RF1 may be spaced apart in the thickness direction from a member located on the upper surface of the light-emitting element LE, for example, the first capping layer CAP1. Accordingly, the first reflective layer RF1 does not directly contact a member located on the upper surface of the light-emitting element LE, such as the first capping layer CAP1.

Hereinafter, a manufacturing process of the display device 10 according to one or more embodiments will be described with reference to other drawings.

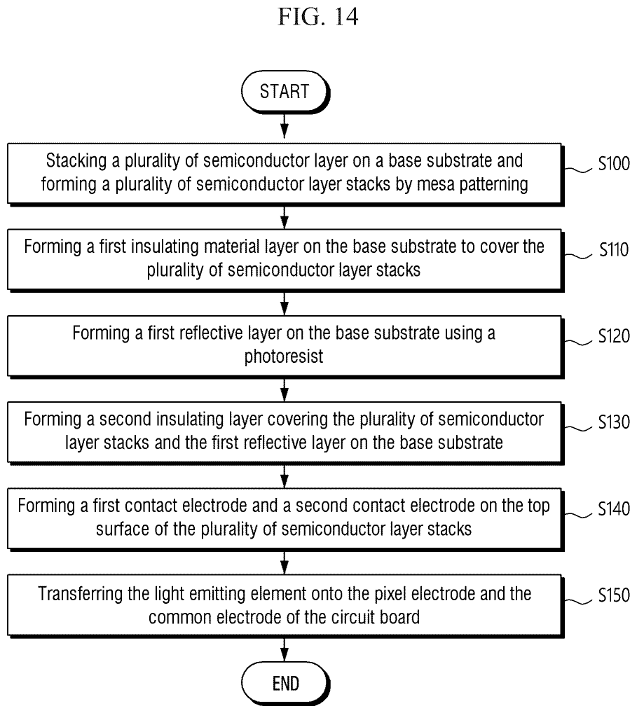

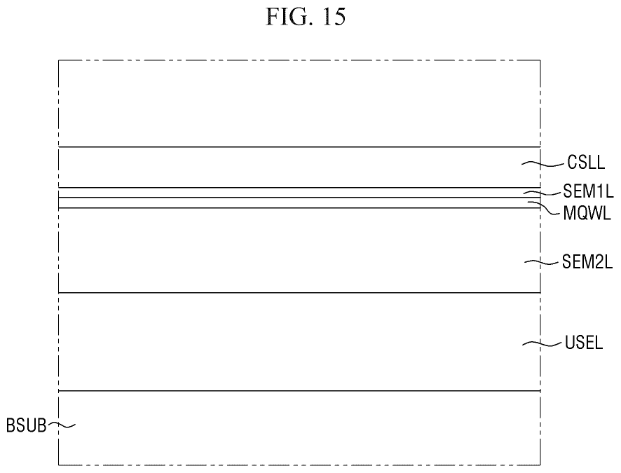

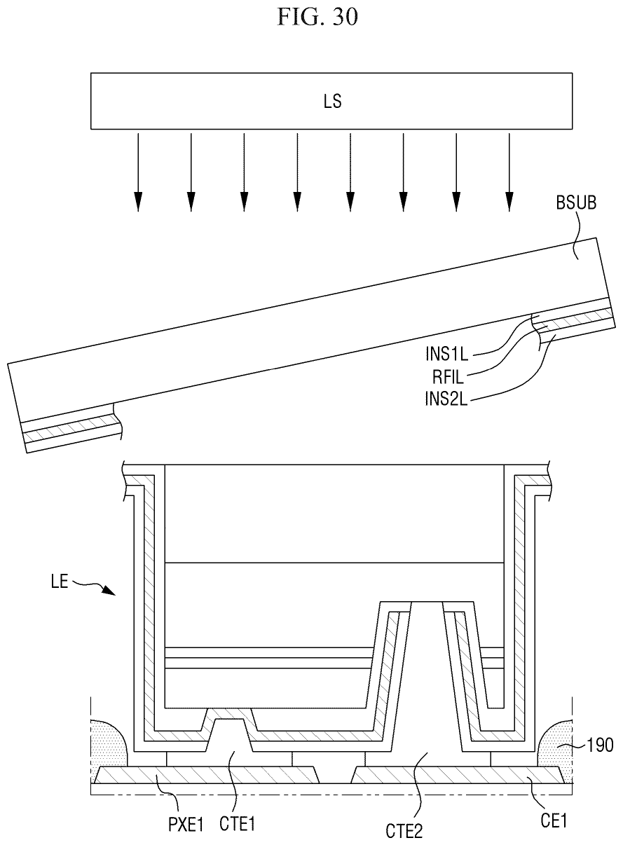

FIG. 14 is a flowchart illustrating a method of manufacturing a display device according to one or more embodiments. FIGS. 15 to 29 are diagrams to illustrate a method of manufacturing a display device according to one or more embodiments. FIG. 30 is a diagram to illustrate a method for separating a light-emitting element from a base substrate according to one or more embodiments.

FIGS. 15 to 29 illustrate cross-sectional views of the structure according to the formation order of each layer of the display device 10. FIGS. 15 to 29 illustrate the manufacturing process of the light-emitting element layer LEL of the display device 10, which can be roughly correspond to the cross-sectional view of FIG. 8, respectively. Furthermore, the following will focus on the first sub-pixel SPX1 of the display device 10. In the following, a method of manufacturing the display device illustrated in FIGS. 15 to 29 will be described in conjunction with FIG. 14.

Referring to FIG. 14, the manufacturing method of the display device 10 according to one or more embodiments may include stacking a plurality of semiconductor layer on a base substrate and forming a plurality of semiconductor layer stacks by mesa patterning (S100), forming a first insulating material layer on the base substrate to cover the plurality of semiconductor layer stacks (S110), forming a first reflective layer using photoresist on the base substrate (S120), forming a second insulating layer covering the plurality of semiconductor layer stacks and the first reflective layer on the base substrate (S130), forming a first contact electrode electrically connected to the first semiconductor layer and a second contact electrode electrically connected to the second semiconductor layer on the top surface of the plurality of semiconductor layer stacks (S140), and transferring the light-emitting element onto the pixel electrode and the common electrode of the circuit board (S150).

First, referring to FIGS. 15 to 17, a plurality of semiconductor material layers stacked on a base substrate BSUB are stacked and mesa-patterned to form a plurality of semiconductor layer stacks (S100 in FIG. 14).

Referring to FIG. 15, the base substrate BSUB is prepared. The base substrate BSUB may be a sapphire substrate Al₂O₃ or a silicon wafer including silicon. However, it is not limited thereto, and in one or more embodiments, a case where the base substrate BSUB is a sapphire substrate will be described as an example.

A plurality of semiconductor material layers SEM3L, SEM2L, MQWL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like, and may be formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group, such as a methyl or ethyl group. For example, it may be a compound, such as trimethyl gallium (Ga(CH₃)₃), trimethyl aluminum (Al(CH₃)₃), or triethyl phosphate ((C₂H₅)₃PO₄), but is not limited thereto.

For example, a third semiconductor material layer USEL is formed on the base substrate BSUB. While the drawings illustrate the third semiconductor material layer USEL being further stacked, it is not limited to this, and a plurality of layers may be formed. The third semiconductor material layer USEL may reduce a lattice constant difference between a second semiconductor material layer SEM2L and the base substrate BSUB. For example, the third semiconductor material layer USEL may include an undoped semiconductor, which may be an n-type or p-type undoped material. In one or more embodiments, the third semiconductor material layer USEL may be at least one of undoped InAlGaN, GaN, AlGaN, InGaN, AlN, or InN, but is not limited thereto.

The second semiconductor material layer SEM2L, the active material layer MQWL, and the first semiconductor material layer SEM1L are sequentially formed on the third semiconductor material layer USEL by using the above-described method. Next, a current-spreading material layer CSLL is formed on the first semiconductor material layer SEM1L.

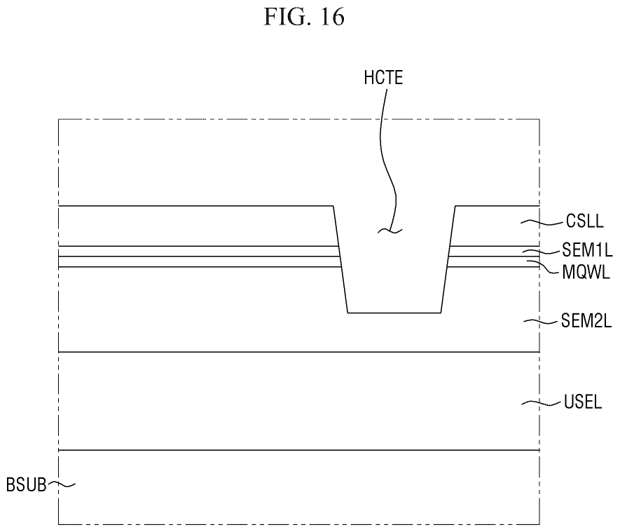

Next, referring to FIG. 16, a downwardly concave groove HCTE is formed on the plurality of semiconductor material layers by an etching process.

The concave groove HCTE penetrates the current-spreading material layer CSLL, the first semiconductor material layer SEM1L, and the active layer MQWL, and is formed to be concave in a downward direction on the second semiconductor material layer SEM2L. To this end, a plurality of first mask patterns are formed on the current-spreading material layer CSLL. The first mask pattern may be a hard mask containing an inorganic material or a photoresist mask including an organic material. The first mask pattern reduces or prevents the likelihood of the lower semiconductor material layers USEL, SEM2L, MQWL, and SEM1L being etched. Next, a groove HCTE may be formed by etching (1^{st} etch) a portion of the plurality of semiconductor material layers using the plurality of first mask patterns as a mask.

The semiconductor material layers may be etched by conventional methods. For example, the process of etching the semiconductor material layers may be dry etching, wet etching, reactive ion etching (RIE), deep reactive ion etching (DRIE), inductively coupled plasma reactive ion etching (ICP-RIE), or the like. In the case of dry etching method, anisotropic etching is possible and may be suitable for vertical etching. When using the etching method described above, the etching etchant may be Cl₂ or O₂. However, it is not limited to this.

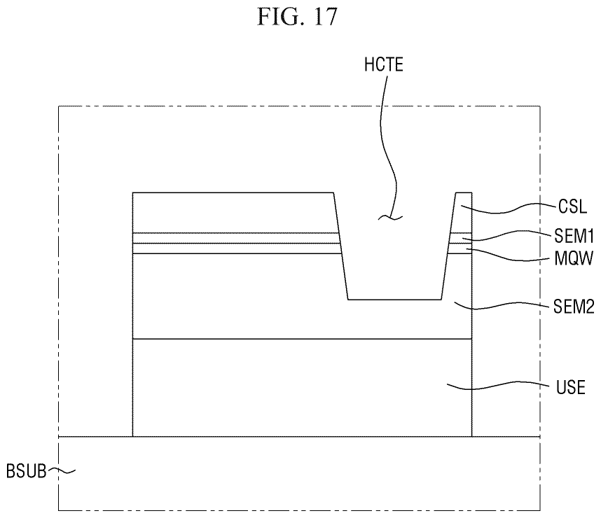

Next, referring to FIG. 17, a plurality of semiconductor material layers USEL, SEM2L, MQWL, SEM1L, and CSLL are etched into a mesa shape to form a plurality of semiconductor layer stacks USE, SEM2, MQW, SEM1, and CSL. The plurality of semiconductor layer stacks may include an undoped semiconductor layer USEM, a second semiconductor layer SEM2, an active layer MQW, a first semiconductor layer SEM1, and a current-spreading layer CSL sequentially stacked.

To this end, a plurality of second mask patterns are formed on the current-spreading material layer CSLL. The first mask pattern may be a hard mask including an inorganic material or a photoresist mask including an organic material. The first mask pattern reduces or prevents the likelihood of the lower semiconductor material layers USEL, SEM2L, MQWL, and SEM1L being etched. Then, a portion of the plurality of semiconductor material layers is etched (2^{nd} etch) using the plurality of second mask patterns as masks to form a semiconductor layer stack.

On the base substrate BSUB, portions of the semiconductor material layers USEL, SEM2L, MQWL, and SEM1L and the current-spreading material layer CSLL that do not overlap with the second mask pattern are etched and removed, and the portions that are not etched due to overlapping with the second mask pattern may be formed into a plurality of semiconductor layer stacks.

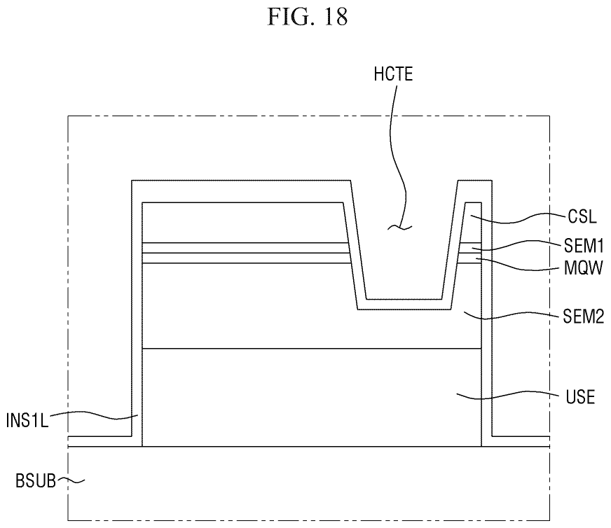

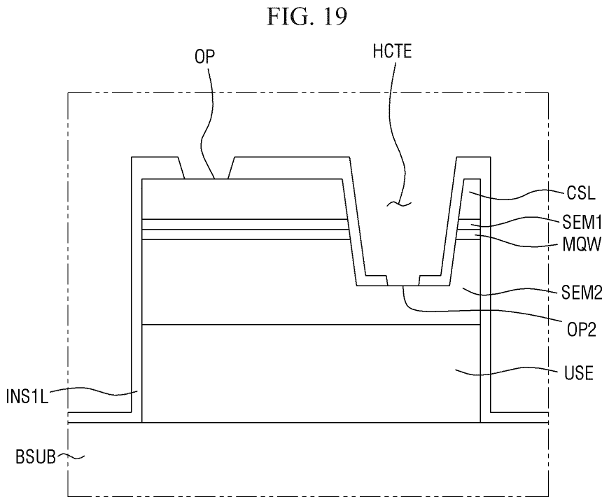

Next, with reference to FIGS. 18 and 19, a first insulating material layer INS1L having a first opening OP1 and a second opening OP2 is formed on the base substrate BSUB on which the semiconductor layer stack including the HCTE is formed (S110 in FIG. 14).

For example, an insulating material layer INSL is formed on the outer surface of the semiconductor layer stack. The insulating material layer INSL may be formed on the entire surface of the base substrate BSUB and may be formed not only on the semiconductor layer stack, but also on the top surface of the base substrate BSUB exposed by the semiconductor layer stack.

Next, etching is performed to partially remove the insulating material layer INSL to form a first insulating material layer INS1L having a first opening OP1 and a second opening OP2 on the top surface of the semiconductor layer stack. The second opening OP2 may be located in the center of the groove HCTE. In this process, a portion of the first insulating material layer INS1L may be removed to expose the top surface of the current-spreading layer CSL and the second semiconductor layer SEM2. A portion of the first insulating material layer INS1L at the center of the groove HCTE may be removed to expose the second semiconductor layer SEM2. The process of partially removing the insulating material layer INSL may be performed through an anisotropic dry etching followed by an etch-back process but is not limited to this.

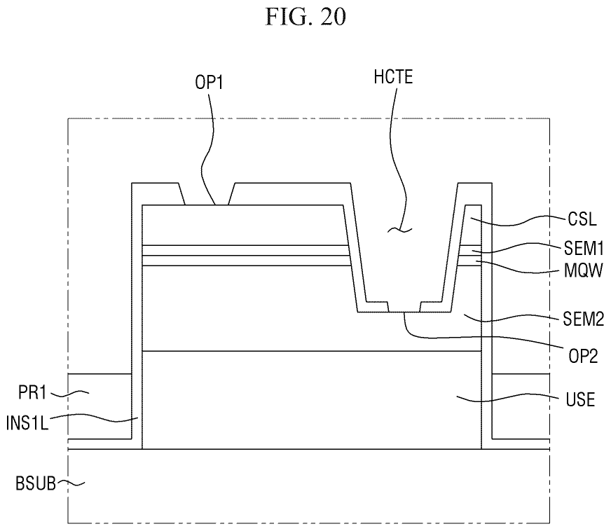

Next, referring to FIGS. 20 to 23, a first reflective layer RF1 of a desired height is formed on the first insulating material layer INS1L using a photoresist PR1.

For example, referring to FIG. 20, the first photoresist PR1 is applied to cover the top surfaces of the plurality of semiconductor layers USE, SEM2, MQWL, and SEM1 and the current-spreading layer CSL to flatten them. Then, the first photoresist PR1 is partially exposed to expose a portion of the top and side surfaces of the plurality of semiconductor layers USE, SEM2, MQWL, and SEM1 and the current-spreading layer CSL. For example, according to this, the first photoresist PR1 may be partially removed to expose at least a first semiconductor layer SEM1 of the light-emitting element LE and at least a portion of the second semiconductor layer SEM2 including the active layer MQW. The first photoresist PR1 remaining from this process may have a thickness of approximately 3 μm in part on the base substrate BSUB but is not limited thereto.

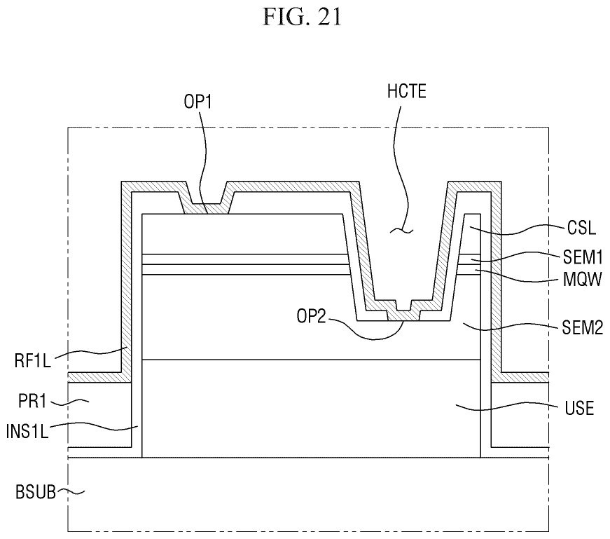

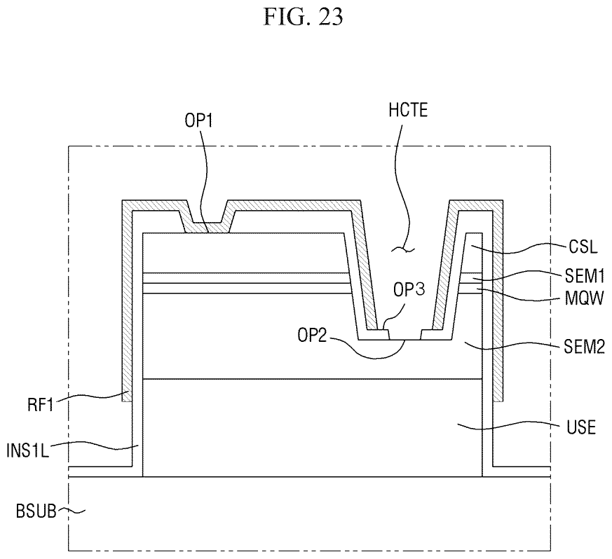

Next, referring to FIGS. 21 and 23, a first reflective layer RF1 is formed on the base substrate BSUB using a first photoresist PR1 (S120 in FIG. 14).

Meanwhile, an adhesive layer may be further formed overlapping a plurality of semiconductor layer stacks and between the first protective material layer INS1L and the first reflective material layer RF1L. The adhesive layer may be made of Cr, Ti, or the like. The adhesive layer may reduce or prevent the likelihood of the first reflective layer RF1 being peeled off when the first photoresist PR1 is removed in a subsequent process. If the adhesive layer is used in this way, the adhesive layer may remain between the first protective layer INS1 and the first reflective layer RF1 of the light-emitting element LE that has been manufactured.

First, referring to FIG. 21, a first reflective material layer RF1L is formed on the first photoresist PR1 where a portion of the plurality of semiconductor layer stacks 1 is exposed. The first reflective material layer RF1L may be deposited by a process, such as stuffing but is not limited thereto. For example, the reflective material layer RFL formed on the first photoresist PR1 is removed by a lift-off process. The lift-off process may be performed, for example, by spraying high-pressure water.

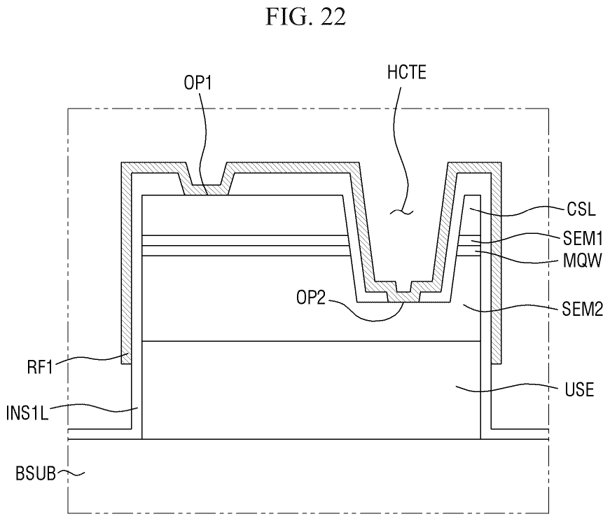

Then, referring to FIG. 22, the first photoresist PR1 remaining on the base substrate BSUB is removed by stripping or ashing. In another example, a second photoresist that protects the plurality of semiconductor layer stacks may be applied on the plurality of semiconductor layer stacks, and the reflective material layer RFL formed on the first photoresist PR1 may be removed through an etching process.

As a result, the first reflective layer RF1 may be formed on the first protective layer INS1 to surround at least the outer surface of the plurality of semiconductor layer stacks and to be spaced apart from the sapphire substrate. Further, the first reflective layer RF1 contacts the first semiconductor layer SEM1 through the first opening OP1, and the first reflective layer RF1 contacts the second semiconductor layer SEM2 through the second opening OP2.

Then, referring to FIG. 23, the first reflective layer RF1 on the second opening OP2 is etched using a mask. Accordingly, a third opening OP3 of the first reflective layer RF1 may be formed, so that the second semiconductor layer SEM2 may be exposed.

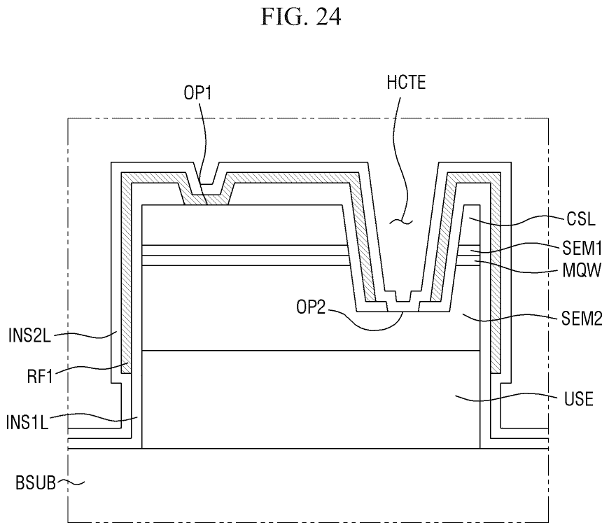

Next, referring to FIGS. 24 to 26, a second insulating layer INS2 is formed on the base substrate BSUB to cover the plurality of semiconductor layer stacks and the first reflective layer RF1 (S130 in FIG. 14).

First, referring to FIG. 24, a second insulating material layer INS2L is formed on the base substrate BSUB to cover the plurality of semiconductor layer stacks and the first reflective layer RF1. The method of forming the second insulating material layer INS2L may be the same as the manufacturing process of the first insulating material layer INS1L.

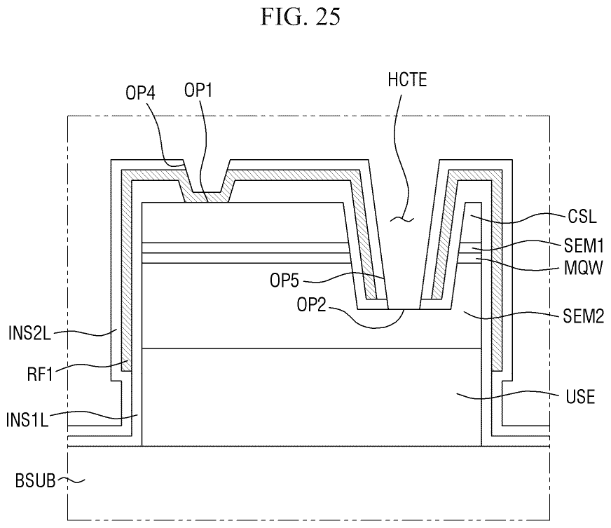

Next, referring to FIG. 25, a fourth opening OP4 and a fifth opening OP5 are formed to respectively overlap the first opening OP1 and the second opening OP2. For example, the fourth opening OP4 overlaps the first opening OP1, and the fifth opening OP5 overlaps the second opening OP2. Accordingly, the fourth opening OP4 exposes the first reflective layer RF1, and the fifth opening OP5 exposes the second semiconductor layer SEM2.

The process of forming the fourth opening OP4 and the fifth opening OP5 may be the same as the process of forming the first opening OP1 and the second opening OP2. For example, etching may be performed to partially remove the second insulating material layer INS2L to form the fourth opening OP4 and the fifth opening OP5 exposing a plurality of semiconductor layer stacks and a portion of the first reflective layer RF1.

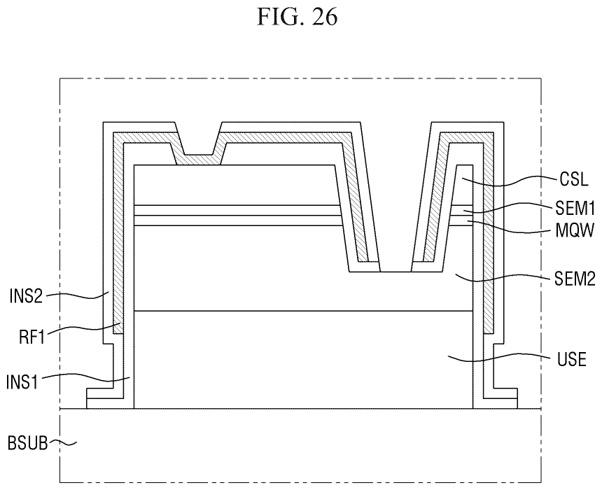

Next, referring to FIG. 26, the first insulating material layer INS1L and the second insulating material layer INS2L on the base substrate BSUB excluding the plurality of semiconductor layer stacks are etched and partially removed. Through this process, the light-emitting element may be easily separated from the base substrate BSUB in the light-emitting element transfer process described later.

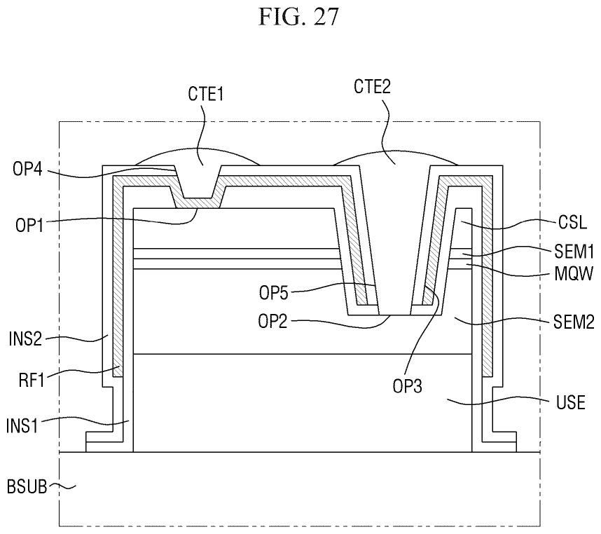

Next, referring to FIG. 27, a first contact electrode CTE1 electrically connected to the first semiconductor layer SEM1, and a second contact electrode CTE2 electrically connected to the second semiconductor layer SEM2, are formed on the top surface of the plurality of semiconductor layer stacks (S140 in FIG. 14).

After stacking an electrode material layer on the entire surface of the base substrate BSUB to cover the fourth opening OP4 and the fifth opening OP5, a portion of the electrode material layer is etched by an etching process to form the first contact electrode CTE1 overlapping the fourth opening OP4, and the second contact electrode CTE2 overlapping the fifth opening OP5. The first contact electrode CTE1 contacts the first reflective layer RF1 through the fourth opening OP4. Because the first reflective layer RF1 contacts the current-spreading layer CSL through the first opening OP1, the first contact electrode CTE1 may be electrically connected to the first semiconductor layer SEM1. The second contact electrode CTE2 may be electrically connected to the second semiconductor layer SEM2 through the fifth opening OP5, the third opening OP3, and the second opening OP2 formed in the groove HCTE.

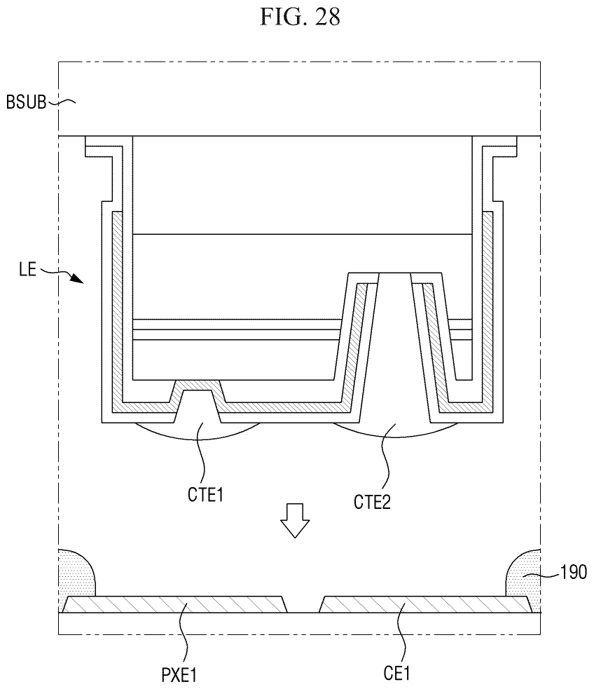

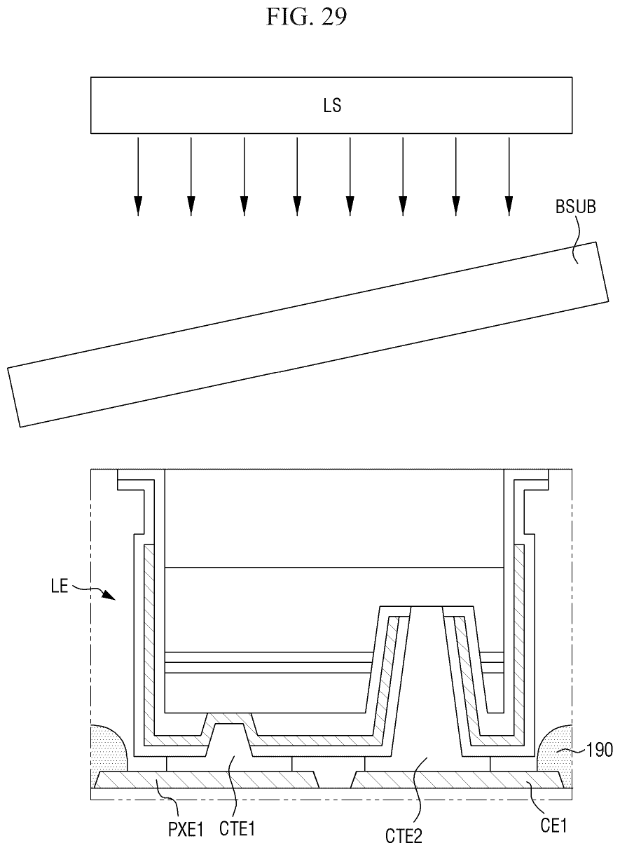

Next, referring to FIGS. 28 and 29, the light-emitting element LE is transferred onto the pixel electrode PXE1 and the common electrode CE1 of the circuit board (S150 in FIG. 14).

The light-emitting element LE of the base substrate BSUB manufactured in FIG. 27 is transferred to the target substrate. In one or more embodiments, the target substrate is described as a circuit board for convenience of explanation, but it is not limited thereto. For example, the target substrate may be a relay substrate.

The light-emitting element LE of the base substrate BSUB is aligned to a desired position on the target substrate. For example, the first contact electrode CTE1 may be located on the pixel electrode PXE1 of the circuit board, and the second contact electrode CTE2 may be located on the common electrode CE1. Then, as shown in FIG. 29, a laser beam is irradiated to the base substrate BSUB through the laser device LS to separate the light-emitting elements LE from the base substrate BSUB. The base substrate BSUB is separated from each undoped semiconductor layer USE of the plurality of light-emitting elements LE.

The process of separating the base substrate BSUB may be done using a laser lift off (LLO) process. The laser lift-off process uses a laser, and a KrF excimer laser (e.g., about 248 nm wavelength) may be used as a source. The energy density of the excimer laser is irradiated in the range of about 550 mJ/cm² to 950 mJ/cm², and the incident area may be in the range of about 50×50 μm² to about 1×1 cm² but is not limited thereto. By irradiating the base substrate BSUB with a laser, the base substrate BSUB may be separated from the light-emitting element LE.

On the other hand, referring to FIG. 30, when the first insulating material layer INS1L, the first reflective material layer RFL1, and the second insulating material layer INS2L remain on the base substrate BSUB, abnormal separation of the light-emitting element LE, or non-separation of the light-emitting element LE, may occur when separating the light-emitting element LE from the base substrate BSUB. In addition, one end of the first reflective layer RF1 may be exposed, and may react with a chemical solution during subsequent processes, thereby deteriorating the characteristics of the light-emitting element LE. For example, the chemical may penetrate from the outside of the first reflective layer RF1 to form a void, or the first reflective layer RF1 contacting the chemical may be deformed.

Next, as shown in FIG. 8, the third organic layer 191 is formed on the substrate 110 on which the light-emitting elements LE are formed. The third organic layer 191 may cover a portion of the side surfaces of the bank 190 and the plurality of light-emitting elements LE. The third organic layer 191 may be formed by being applied using a solution process, such as spin coating, inkjet printing, or the like, and patterned using an exposure process.

Then, as shown in FIG. 7, a first capping layer CAP1, a light-blocking layer BM, a light transmission layer TPL, a first light conversion layer QDL, and a second light conversion layer QDL2 are formed on the light-emitting element LE and the third organic layer 191, such that the display device 10 according to one or more embodiments may be manufactured.

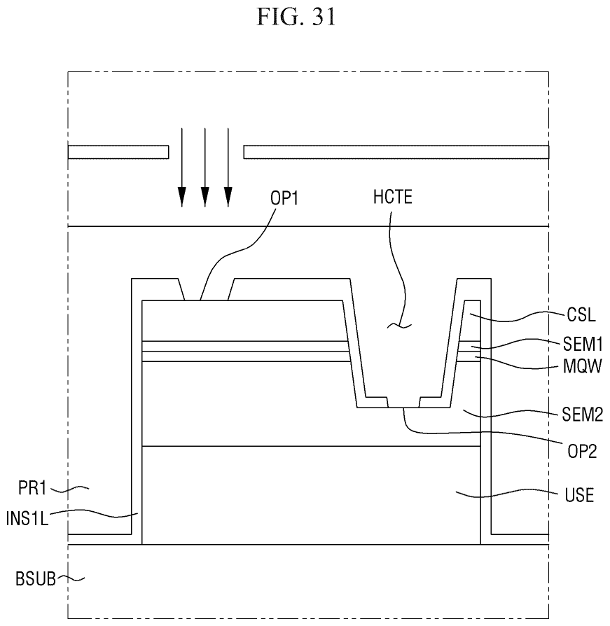

FIGS. 31 to 34 are drawings for forming a first reflective layer according to one or more other embodiments.

Referring to FIG. 19, a process for forming a first reflective layer RF1 after a process for forming a first insulating material layer INS1L defining a first opening OP1 and a second opening OP2 on a plurality of semiconductor layer stacks will be described.

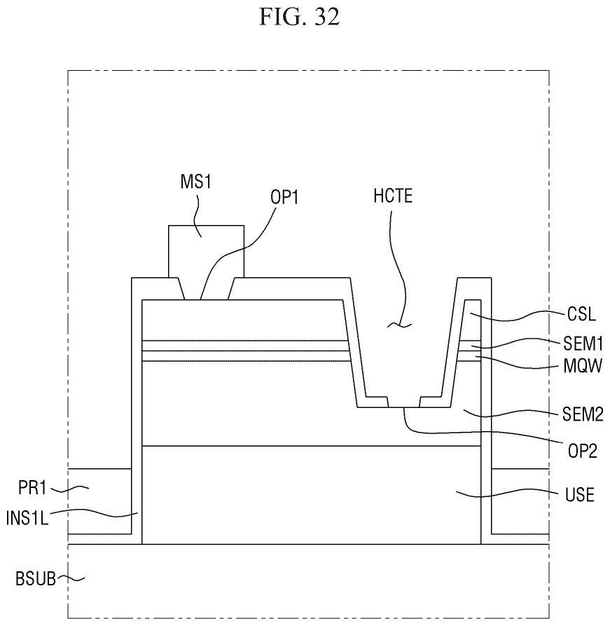

First, referring to FIGS. 31 and 32, a first photoresist PR1 is applied to cover the plurality of semiconductor layer stacks, and is planarized. Then, the first photoresist PR1 is partially exposed using a mask pattern. The first photoresist PR1 may be a negative photoresist. The negative photoresist may be left as the first mask MS1 on the first portion overlapping the first opening OP1 of the plurality of semiconductor layer stacks. Further, a portion of the first photoresist PR1 may be removed to expose at least a portion of the plurality of semiconductor layer stacks. The first photoresist PR1 remaining from this process may have a thickness of approximately 3 μm in part on the base substrate BSUB but is not limited thereto.

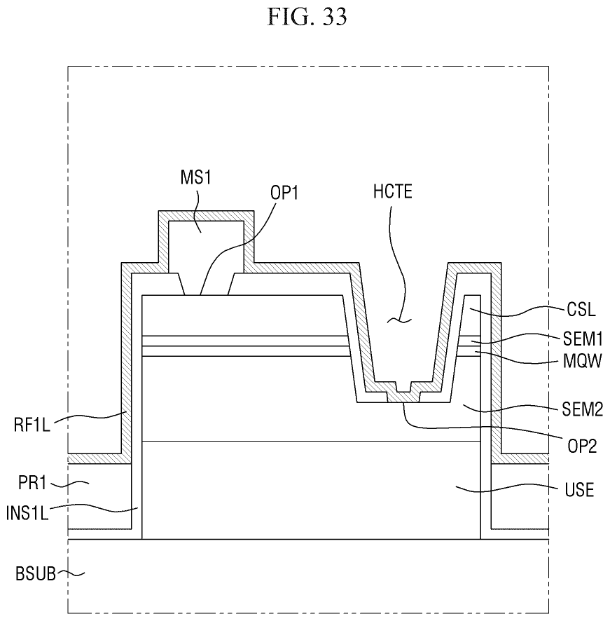

Referring to FIG. 33, a first reflective material layer RF1L is deposited on the entire surface of the base substrate BSUB to cover the plurality of semiconductor layer stacks and the first photoresist PR1 on which the first mask MS1 is formed.

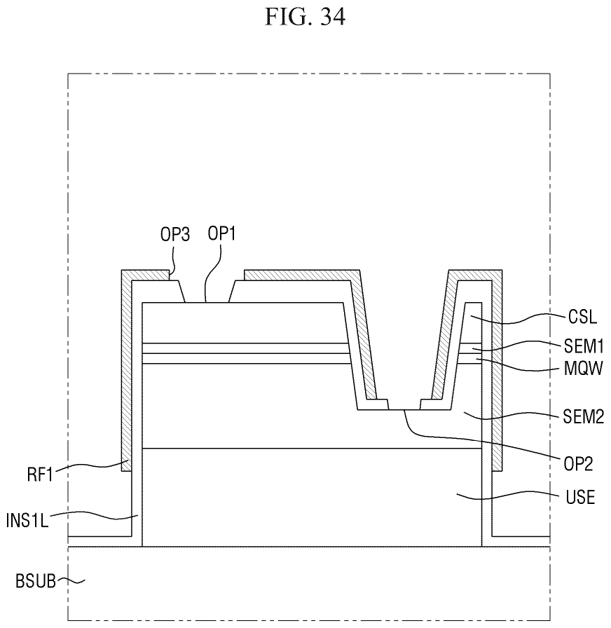

Then, referring to FIG. 34, the first photoresist PR1 and the first mask MS1 are removed. Through this process, the first reflective layer RF1 having the third opening OP3 overlapping the first opening OP1 may be formed on the outer surface of the plurality of semiconductor layer stacks. The first reflective layer RF1 may contact the second contact electrode CTE2 and may not contact the first contact electrode CTE1.

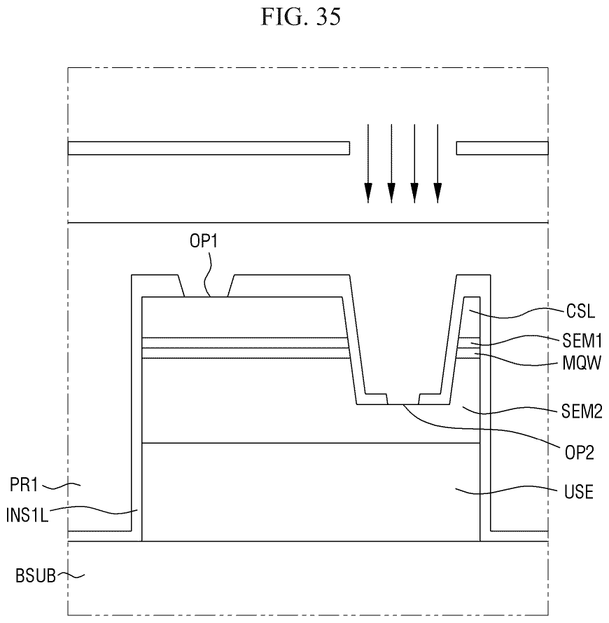

FIGS. 35 to 38 are diagrams for forming a first reflective layer according to one or more other embodiments.

Referring to FIG. 19, a process for forming a first reflective layer RF1 after forming a first insulating material layer INS1L having a first opening OP1 and a second opening OP2 on a plurality of semiconductor layer stacks will be described.

First, referring to FIG. 35, a first photoresist PR1 is applied to cover the plurality of semiconductor layer stacks, and is planarized.

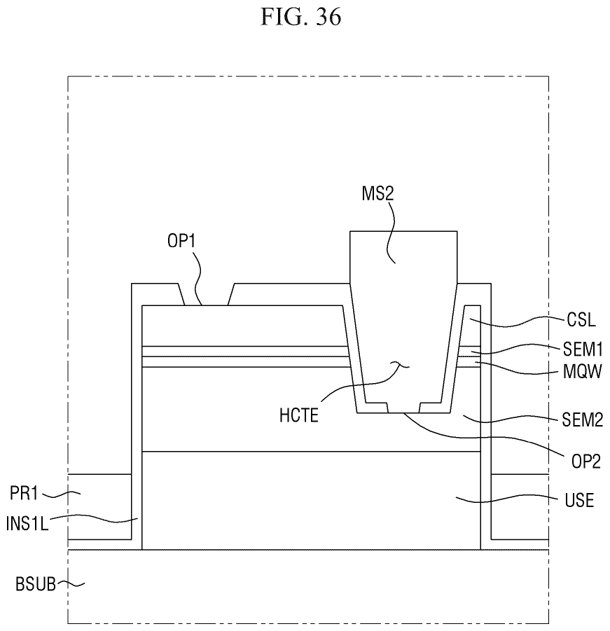

Then, referring to FIG. 36, the first photoresist PR1 is partially exposed using a mask pattern. The first photoresist PR1 may be a negative photoresist. The negative photoresist may be left as the second mask MS2 on the second portion overlapping the second opening OP2 of the plurality of semiconductor layer stacks. The second mask MS2 may overlap the groove HCTE, and may be formed to fill the groove HCTE.

Further, a portion of the first photoresist PR1 may be removed to expose at least a portion of the plurality of semiconductor layer stacks. The first photoresist PR1 remaining from this process may have a thickness of approximately 3 μm in part on the base substrate BSUB, but is not limited thereto.

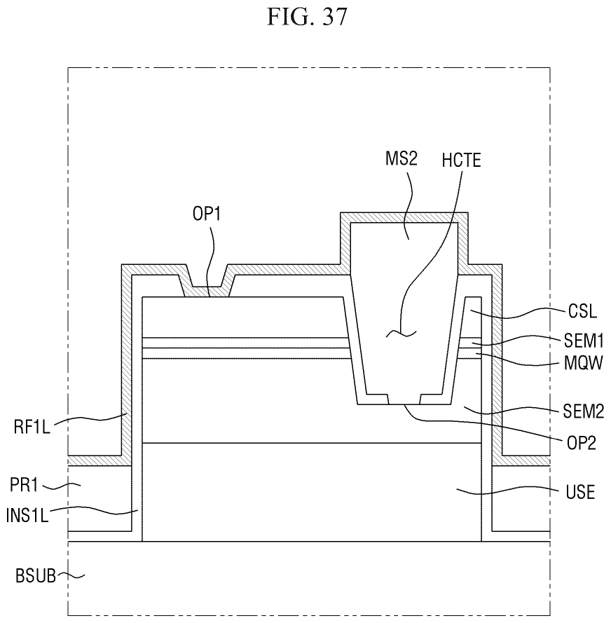

Referring to FIG. 37, a first reflective material layer RF1L is deposited on the entire surface of the base substrate BSUB to cover the plurality of semiconductor layer stacks and the first photoresist PR1 on which the second mask MS2 is formed.

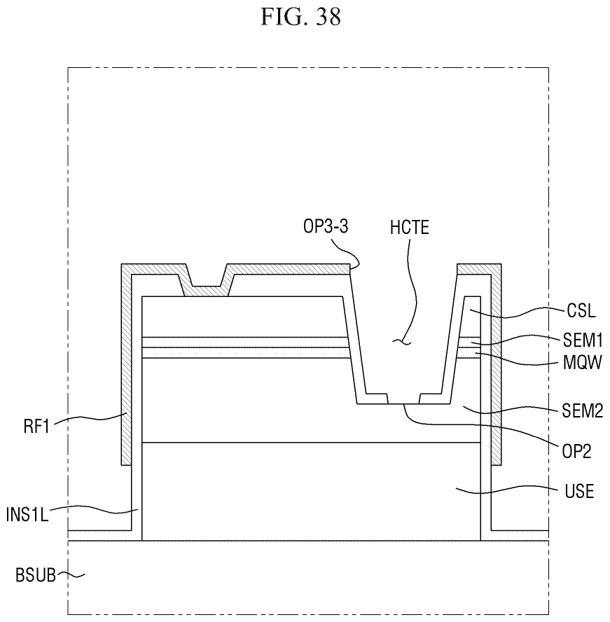

Then, referring to FIG. 38, the first photoresist PR1 and the second mask MS2 are removed. Through this process, the first reflective layer RF1, which defines the third opening OP3-3 overlapping the second opening OP2, may be formed on the outer surface of the plurality of semiconductor layer stacks. The first reflective layer RF1 is not located in the groove HCTE. The first reflective layer RF1 may contact the subsequently located first contact electrode CTE1, and the first reflective layer RF1 may not contact the second contact electrode CTE2.

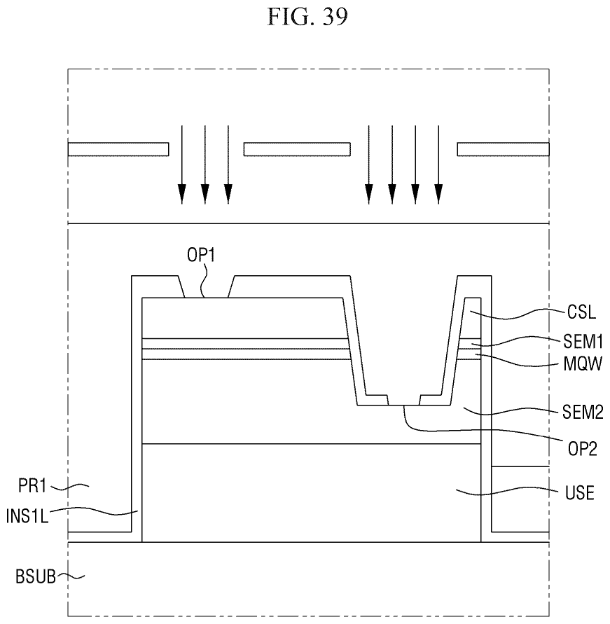

FIGS. 39 to 42 are diagrams for forming a first reflective layer according to one or more other embodiments.

Referring to FIG. 19, a process for forming a first reflective layer RF1 after forming a first insulating material layer INS1L having a first opening OP1 and a second opening OP2 on a plurality of semiconductor layer stacks will be described.

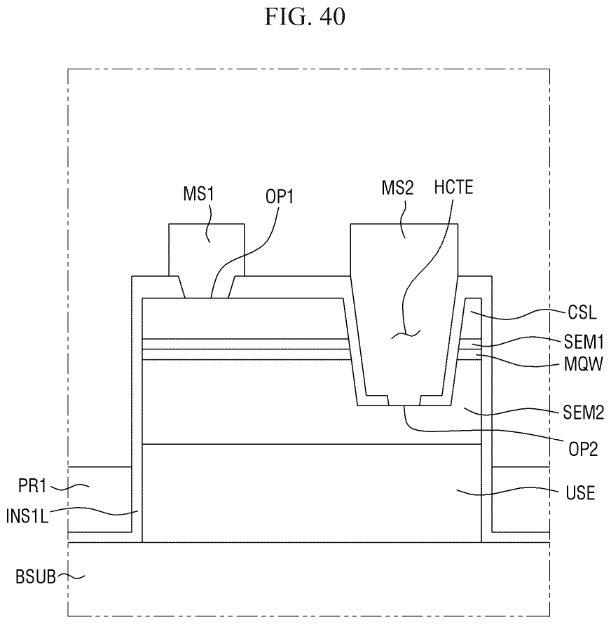

First, referring to FIGS. 39 and 40, the first photoresist PR1 is applied and planarized to cover the plurality of semiconductor layer stacks. Then, the first photoresist PR1 is partially exposed using a mask pattern. The first photoresist PR1 may be a negative photoresist. The negative photoresist may be left as the first mask MS1 on the first portion overlapping the first opening OP1 of the plurality of semiconductor layer stacks. Further, the second mask MS2 may be left on the second portion overlapping the second opening OP2 of the plurality of semiconductor layer stacks. The second mask MS2 may be formed to overlap the groove HCTE and fill the groove HTCE.

In addition, a portion of the first photoresist PR1 may be removed to expose at least a portion of the plurality of semiconductor layer stacks. The first photoresist PR1 remaining from this process may have a thickness of approximately 3 μm in part on the base substrate BSUB but is not limited thereto.

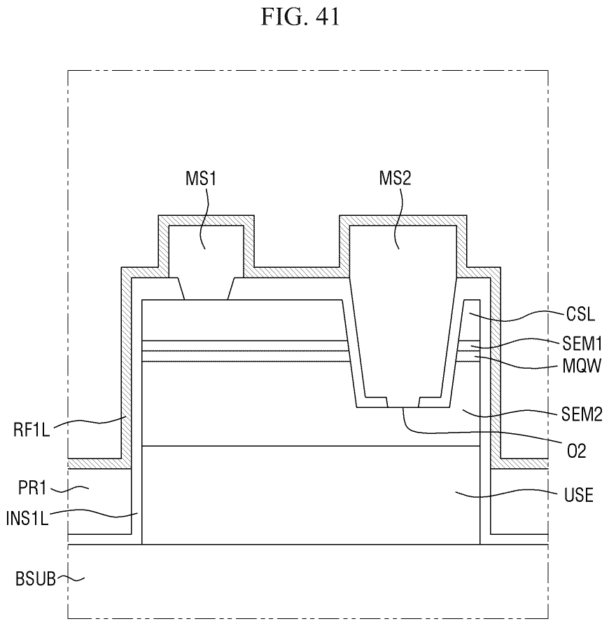

Referring to FIG. 41, a first reflective material layer RF1L is deposited on the entire surface of the base substrate BSUB to cover the first photoresist PR1 and the plurality of semiconductor layer stacks formed by the first mask MS1 and the second mask MS2.

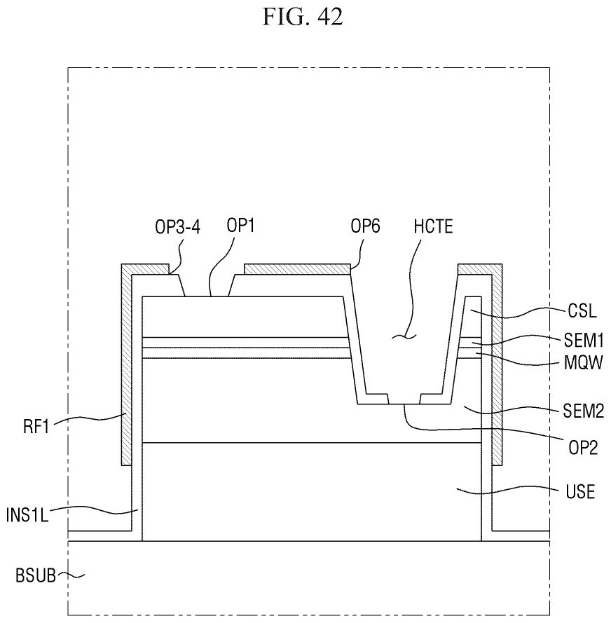

Then, referring to FIG. 42, the first photoresist PR1, the first mask MS1, and the second mask MS2 are removed. In this process, the first reflective layer RF1 having the third opening OP3-4 overlapping on the first opening OP1 and the sixth opening OP6 overlapping on the second opening OP2 may be formed on the outer surface of the plurality of semiconductor layer stacks. The first reflective layer RF1 is not located in the groove HCTE. The first reflective layer RF1 may not contact the first and second contact electrodes CTE1 and CTE2 that are subsequently located thereon.

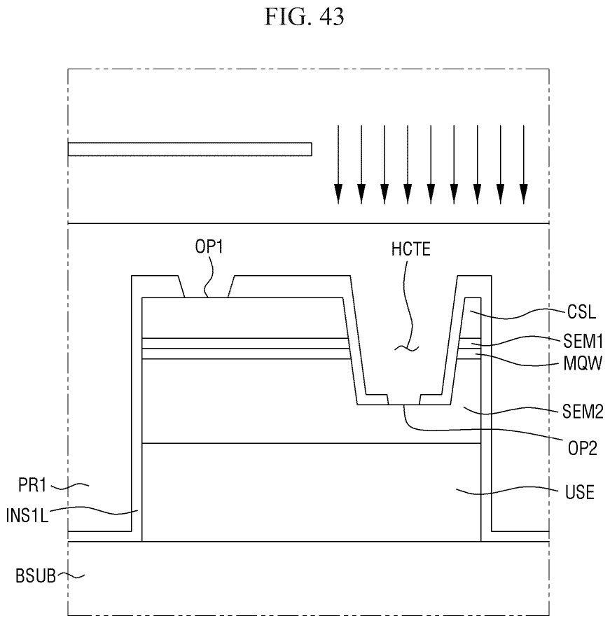

FIGS. 43 to 46 are diagrams for forming a first reflective layer according to one or more other embodiments.

Referring to FIG. 19, a process for forming a first reflective layer RF1 after forming a first insulating material layer INS1L having a first opening OP1 and a second opening OP2 on a plurality of semiconductor layer stacks will be described.

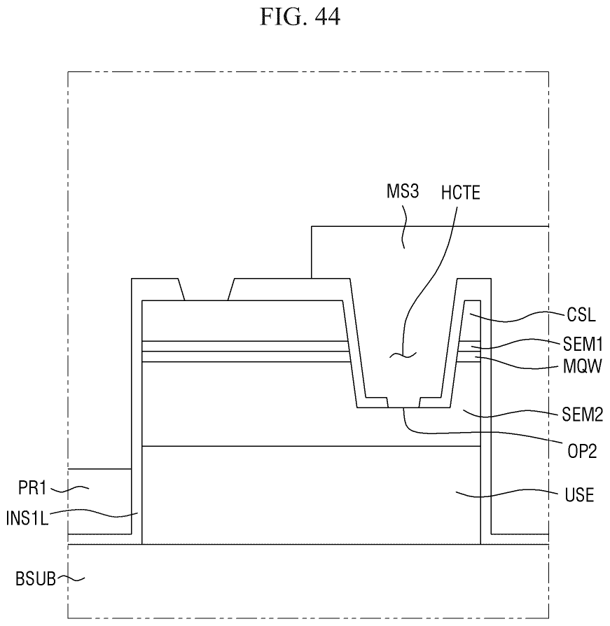

First, referring to FIGS. 43 and 44, the first photoresist PR1 is applied to cover the plurality of semiconductor layer stacks, and is planarized. Then, the first photoresist PR1 is partially exposed using a mask pattern. The first photoresist PR1 may be a negative photoresist. The mask pattern may expose one side of the plurality of semiconductor layer stacks including the groove HCTE.

The negative photoresist may be left as a third mask MS3 to overlap the grooves HCTE of the plurality of semiconductor layer stacks, and may cover one side of the plurality of semiconductor layer stacks. Further, the third mask MS3 may be formed to overlap the groove HCTE, and to fill the groove HCTE.

In addition, a portion of the first photoresist PR1 may be removed to expose at least a portion of the plurality of semiconductor layer stacks. The first photoresist PR1 remaining from this process may have a thickness of approximately 3 μm in part on the base substrate BSUB but is not limited thereto.

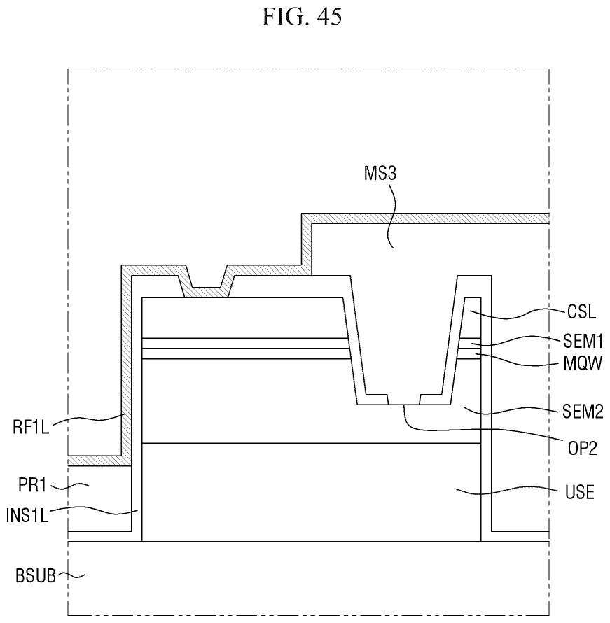

Referring to FIG. 45, a first reflective material layer RF1L is deposited on the entire surface of the base substrate BSUB to cover the plurality of semiconductor layer stacks and the first photoresist PR1 on which the third mask MS3 is formed.

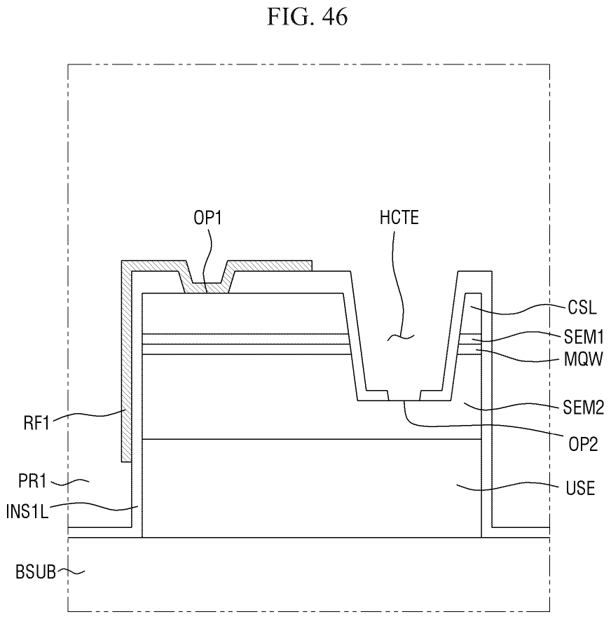

Then, referring to FIG. 46, the first photoresist PR1 and the third mask MS3 are removed. Through this process, the first reflective layer RF1 exposing the groove HCTE and one side of the plurality of semiconductor layer stacks may be formed on the outer surface of the plurality of semiconductor layer stacks. The first reflective layer RF1 is not located in the groove HCTE. The first reflective layer RF1 may contact the subsequently located first contact electrode CTE1, and may not contact the second contact electrode CTE2.

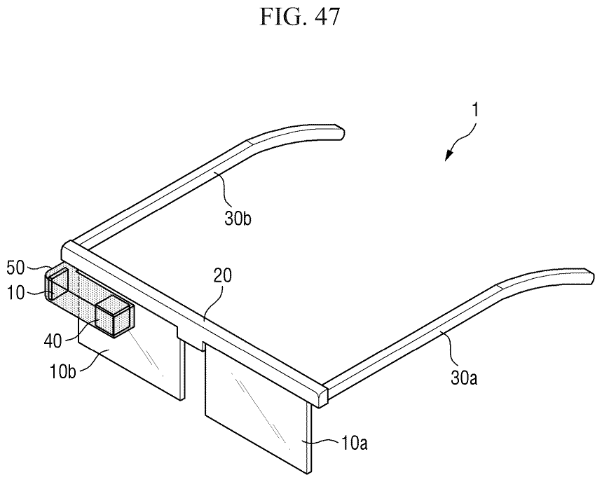

FIG. 47 is a diagram illustrating a virtual reality device including a display device according to one or more embodiments. FIG. 47 illustrates a virtual reality device 1 in which the display device 10 according to one or more embodiments is used.

Referring to FIG. 47, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 47 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 47, and may be applied in various forms and in various electronic devices.

The display device housing 50 may receive the display device 10 and the reflective member 40. An image displayed on the display device 10 may be reflected from the reflective member 40, and may be provided to a user's right eye through the right-eye lens 10b. Thus, the user may view a virtual reality image displayed on the display device 10 via the right eye.

FIG. 47 illustrates that the display device housing 50 is located at a right end of the support frame 20. However, one or more embodiments of the disclosure is not limited thereto. For example, the display device housing 50 may be located at a left end of the support frame 20. In this case, the image displayed on the display device 10 may be reflected from the reflective member 40, and may be provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

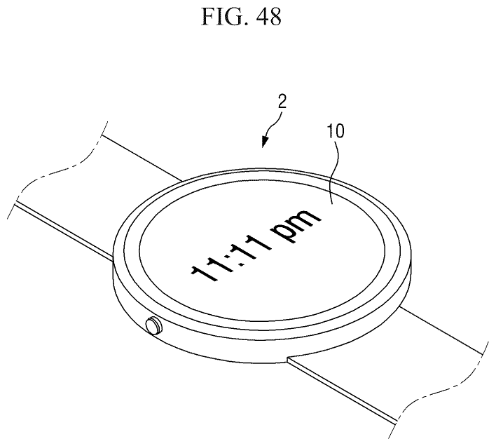

FIG. 48 is a diagram illustrating a smart device including a display device according to one or more embodiments.

Referring to FIG. 48, a display device 10 according to one or more embodiments may be applied to a smart watch 2 as one of smart devices.

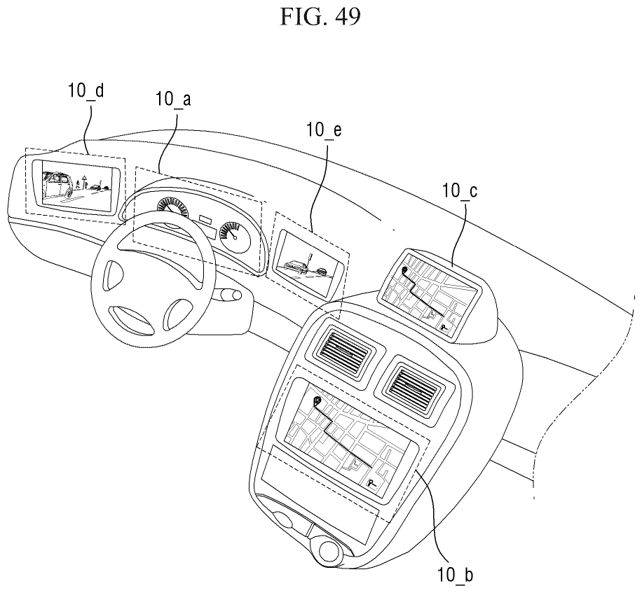

FIG. 49 is a diagram illustrating a vehicle including a display device according to one or more embodiments. FIG. 49 illustrates a vehicle in which display devices according to one or more embodiments are used.

Referring to FIG. 49, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

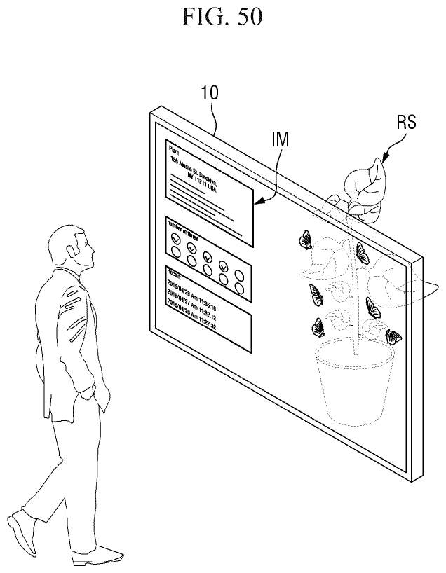

FIG. 50 is a diagram illustrating a transparent display device including a display device according to one or more embodiments.

Referring to FIG. 50, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate 110 of the display device 10 shown in FIG. 7 may include a light-transmitting portion that may transmit light therethrough, or may be made of a material that may transmit light therethrough.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a substrate;
a pixel electrode and a common electrode above the substrate and spaced apart from each other; and
a light-emitting element comprising:
a first contact electrode above the pixel electrode;
a second contact electrode above the common electrode;
semiconductor layer stacks;
a first protective layer surrounding the semiconductor layer stacks in plan view;
a reflective layer on the first insulating layer, surrounding the semiconductor layer stacks in plan view, and not contacting the first contact electrode or the second contact electrode; and
a second protective layer on the reflective layer and the first insulating layer, and surrounding the semiconductor layer stacks in plan view.

2. The display device of claim 1, wherein the reflective layer defines an opening overlapping the first contact electrode or the second contact electrode.

3. The display device of claim 1, wherein one end of the reflective layer is adjacent a side surface of the semiconductor layer stacks, and has a height that is lower than a height of the semiconductor layer stacks.

4. The display device of claim 3, wherein the semiconductor layer stacks comprise an undoped semiconductor layer, a second semiconductor layer, an active layer, a first semiconductor layer, and a current-spreading layer.

5. The display device of claim 4, wherein the reflective layer is adjacent side surfaces of the first semiconductor layer, the active layer, and the second semiconductor layer, and is adjacent a portion of a side surface of the undoped semiconductor layer.

6. The display device of claim 3, wherein the second protective layer covers one end of the reflective layer, and directly contacts the first protective layer.

7. The display device of claim 4, wherein the semiconductor layer stacks define a downwardly convex groove penetrating the current-spreading layer, the first semiconductor layer, the active layer, and a portion of the second semiconductor layer, and
wherein the second contact electrode is in the groove, and is electrically connected to the second semiconductor layer.

8. The display device of claim 7, wherein the first protective layer directly contacts one surface of the semiconductor layer stacks, defines a first opening and a second opening adjacent another surface of the semiconductor layer stacks, and is adjacent a side of the groove, and
wherein the second opening is adjacent a bottom surface of the groove.

9. The display device of claim 8, wherein the reflective layer does not overlap the first opening or the second opening,
wherein the first contact electrode is electrically connected to the current-spreading layer through the first opening, and
wherein the second contact electrode is electrically connected to the second semiconductor layer through the second opening.

10. The display device of claim 8, wherein the reflective layer defines an opening that overlaps the first opening or the second opening.

11. The display device of claim 8, wherein the reflective layer is along a side of the groove.

12. A method of manufacturing display device comprising:
forming semiconductor layer stacks by stacking semiconductor material layers on a base substrate and performing mesa patterning;
forming a first insulating material layer above the base substrate to cover the semiconductor layer stacks;
forming a photoresist above the base substrate;
forming a reflective material layer covering the photoresist and the semiconductor layer stacks;
removing the photoresist to form a reflective layer;
forming a second insulating material layer covering the semiconductor layer stacks and the reflective layer above the base substrate; and
forming a light-emitting element by forming a first contact electrode electrically connected to a first semiconductor layer of the semiconductor layer stacks, and a second contact electrode electrically connected to a second semiconductor layer of the semiconductor layer stacks, above a top surface of the semiconductor layer stacks.

13. The method of claim 12, further comprising forming a first protective layer and forming a second protective layer surrounding the semiconductor layer stacks in plan view by etching portions of the first insulating material layer and the second insulating material layer extending from the semiconductor layer stacks to the base substrate.

14. The method of claim 12, further comprising forming a downwardly convex groove in the semiconductor layer stacks through a partial etching process.

15. The method of claim 14, wherein the semiconductor layer stacks comprise an undoped semiconductor layer, the second semiconductor layer, an active layer, the first semiconductor layer, and a current-spreading layer, and
wherein the groove penetrates the current-spreading layer, the first semiconductor layer, the active layer, and a portion of the second semiconductor layer.

16. The method of claim 15, wherein a height of the photoresist is lower than a height of the undoped semiconductor layer.

17. The method of claim 16, wherein the reflective layer does not contact the first contact electrode or the second contact electrode.

18. The method of claim 17, wherein forming the photoresist above the base substrate comprises forming the photoresist at an area to overlap the first contact electrode or an area to overlap the second contact electrode on the top surface of the semiconductor layer stacks using a mask, and
wherein removing the photoresist comprises forming an opening in the reflective layer.

19. The method of claim 14, wherein the reflective material layer is along an inside of the groove in the semiconductor layer stacks.

20. The method of claim 12, wherein, in forming the second insulating material layer, the second insulating material layer covers one end of the reflective layer, and directly contacts the first insulating material layer.
